(19) United States
(12) Patent Application Publication
(10) Pub. No.: US 2025/0298065 A1
(43) Pub. Date: Sep. 25, 2025

(54) REAL-TIME CIRCUIT LINE RESISTOR-CAPACITOR DETECTION

(71) Applicant: Micron Technology, Inc., Boise, ID (US)

(72) Inventors: Jun Xu, San Jose, CA (US); Massimo Rossini, Roma (IT); Kim-Fung Chan, Fremont, CA (US)

(73) Assignee: Micron Technology, Inc., Boise, ID (US)

(21) Appl. No.: 19/063,244

(22) Filed: Feb. 25, 2025

Related U.S. Application Data
(60) Provisional application No. 63/569,014, filed on Mar. 22, 2024.

(51) Int. Cl. G01R 27/02; G01R 19/25; G01R 19/255; G11C 29/12; G11C 29/36

(52) U.S. Cl. CPC G01R 27/02; G01R 19/2506; G01R 19/255; G11C 29/12005; G11C 29/36; G11C 2029/1202

(57) ABSTRACT

A resistor-capacitor (RC) sensor circuit is provided. The circuit includes a regulator configured to drive a circuit line; one or more current mirrors coupled to the regulator to obtain a representative copy of a current of the circuit line; and an integrator comprising an analog-to-digital converter (ADC). The ADC is coupled to the one or more current mirrors to receive the representative copy of the current of the circuit line and is configured to: integrate the representative copy of the current of the circuit line for a plurality of time intervals to obtain a plurality of charges associated with the respective time intervals; and output digital data that is used to calculate an RC time constant. The plurality of time intervals are within a first ramping time period for ramping the far-end voltage of the circuit line from a first voltage value to a second voltage value.

This application claims priority to U.S. Provisional Application No. 63/569,014, filed on Mar. 22, 2024, entitled “REAL-TIME CIRCUIT LINE RESISTOR-CAPACITOR DETECTION,” the content of which is incorporated by reference in its entirety for all purposes.

### TECHNICAL FIELD

This disclosure relates to one or more systems for memory, including techniques for sensing resistor-capacitor (RC) time constant of a circuit line in real time.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIGS. 1A and 1B illustrate an example of a host system and a memory system that support techniques for sensing RC time constant of a circuit line in real time in accordance with examples as disclosed herein.

FIG. 1C is a block diagram of a memory device in communication with a memory system controller of a memory system, in accordance with examples as disclosed herein.

FIGS. 2A-2C are illustrative schematics of portions of an array of memory cells in a memory device, in accordance with examples as disclosed herein.

FIG. 2D illustrates an example of a memory device including multiple blocks of memory cells in accordance with examples as disclosed herein.

FIG. 3 is a block diagram of an example apparatus for implementing one or more systems and for performing one or more methods described herein, in accordance with examples as disclosed herein.

FIG. 4 is a block diagram of an example memory system that supports techniques for sensing RC time constant of a circuit line in real time in accordance with examples as disclosed herein.

FIG. 5A is a schematic of an example word line regulator driving a word line, in accordance with examples as disclosed herein.

FIG. 5B are example relations between the word line current and time for a same time constant with different resistance and capacitance values, in accordance with examples as disclosed herein.

FIG. 5C is a schematic of an example word line regulator, in accordance with examples as disclosed herein.

FIG. 6A is a schematic of an example word line regulator and example current mirrors for obtaining representative copies of pull up and pull-down currents, in accordance with examples as disclosed herein.

FIG. 6B is a schematic of an example word line regulator and another example current mirror for obtaining a representative copy of the pull up current, in accordance with examples as disclosed herein.

FIG. 6C is a schematic of an example word line regulator and an example current mirror for obtaining a representative copy of the resistor divider current, in accordance with examples as disclosed herein.

FIG. 6D is a schematic of an example word line regulator and an example current source for obtaining a representative copy of the resistor divider current, in accordance with examples as disclosed herein.

FIG. 7A is a schematic of an example RC-sensor circuit including a regulator, current mirrors, and an integrator, in accordance with examples as disclosed herein.

FIG. 7B is an example relation between a word line current and the digital data representing the word line current, in accordance with examples as disclosed herein.

FIG. 8A are example relations of a near-end word line voltage, a far-end word line voltage, and a word line current with respect to time in a read operation, in accordance with examples as disclosed herein.

FIG. 8B are example relations of a near-end word line voltage and a far-end word line voltage with respect to time in a program operation, in accordance with examples as disclosed herein.

FIG. 9 illustrates a flowchart showing a method or methods that support techniques for using real-time RC time constant measurement to optimize an access operation in accordance with examples as disclosed herein.

FIGS. 10A and 10B illustrate flowcharts showing a method or methods that support techniques for detecting defects in a target circuit line, in accordance with examples as disclosed herein.

### DETAILED DESCRIPTION

In a memory device or any semiconductor device, there are circuit lines. Circuit lines are used to conduct voltage signals and/or current signals. Circuit lines can be made of metal, alloy, or semiconductor materials (e.g., doped poly-silicon). A circuit line in a memory device includes, for example, a word line, a bit line, a select line (e.g., a source select line or SGS line, a drain select line or SGD line), a common source (e.g., SRC) line, etc. The description herein uses the word line in a memory device as an example, but it is understood that the concept can be applied to other types of circuit lines in a memory device or any other semiconductor devices.

A circuit line may also be referred to as a transmission line for transmitting signals. Circuit lines can be loaded and thus associated with resistances and capacitances. Therefore, the time it takes for a signal to ramp up or ramp down at the near-end of the circuit line may be different from the time it takes for the signal to ramp up or ramp down at the far-end of the circuit line. This is referred to as the propagation delay of the circuit line. The propagation delay of a circuit line relates to the resistance (R) and capacitance (C) of the circuit line and can be measured by the RC time constant, which is the multiplication of the resistance and the capacitance. A memory device has many circuit lines such as word lines. Using the word lines as an example, the circuit configuration and the manufacturing process inevitably make word lines different in many aspects. As a result, the RC time constants of word lines may vary from semiconductor die to die, from block to block, and/or from word line to word line. These variations in RC time constants of the word lines in turn vary the propagation delays of the word lines. As a result, memory device operations (e.g., read, program, erase) may be negatively affected (e.g., slowed).

Other than word line RC time constant variations, the manufacturing process of a memory device may cause word line defects, including an open word line defect or a short word line defect. An open word line defect (or any circuit line) has a break or interruption in the conducting path, preventing the flow of electric current. A short word line (or any circuit line) occurs when there is an unintended connection between two points of the word line and another part of an electrical circuit (e.g., another word line) with very low or negligible resistance, bypassing the intended load or resistance, or bypassing the intended insulation. Both open word line and short word line defects are undesired and can be costly. If there are too many word line defects, the memory device may become excessively leaky, unreliable, non-functional, prone to data loss, or completely inoperable.

To characterize or detect the aforementioned word line RC time constant variations and/or the word line defects, it is desirable or advantageous to measure the word line RC time constants. For example, measuring the RC time constant for each word line of the many word lines in a memory device can provide an estimation of propagation delays or the ramp up/down rates of different word lines. Measuring the RC time constants can also provide indications of whether any particular word lines may be open or short. In some scenarios, the RC time constants measurements may be performed in real time for improved efficiency. A real-time measurement, as described in this disclosure, is integrated into, or becomes a part of, a memory operation (e.g., a read, write, or erase operation). A real-time measurement can be used for optimizing the timing of the same operation or subsequent operations. The real-time measurement of the RC time constant of the word line can be used to compensate for the word line RC time constant variations of different word lines, such that the time allocated for memory device operations (e.g., read, program, erase) can be optimized or improved. Currently, without using the real-time RC time constant measurement techniques described herein, the firmware assumes that for operations (e.g., read, program, erase) of the memory device, all word lines have the worst case (e.g., largest) RC time constant. That is, all word lines are assumed to propagate signal as slow as the word line having the largest RC time constant. This assumption is to make sure that sufficient time is allocated for completing the operations to all word lines. However, some or most word lines may not have the worst-case RC time constant, and therefore assuming all word lines having the worse case RC time constant results in slow and inefficient operations for some or most word lines. As described in more detail below, using the techniques disclosed herein, the RC time constant of a word line can be measured in a first strobe of an operation, and can be used to calculate the time that needs to be allocated to the subsequent strobes of the same operation (e.g., read or program), potentially resulting in a faster operation (e.g., if the word line does not have the worst case RC time constant).

Moreover, the measurement of the RC time constant of a word line can be used to detect a defective word line. For example, an open word line may have abnormally small word line RC time constant because it is broken and thus has no or a smaller loading on the word line. And a short word line may have an abnormal current profile when the word line is being charged or discharged because of leakage or shortage. For instance, the current of a word line may not go to zero and may have a constant small leakage. Thus, even after a sufficiently long time, the word line does not settle or become zero. And if there is a severe short between the word line and other part of a circuit, the current may be abnormally large. Identifying defective word lines in real time can thus help prevent the defective memory device from being used or provided to customers, which in turn prevents potential data loss.

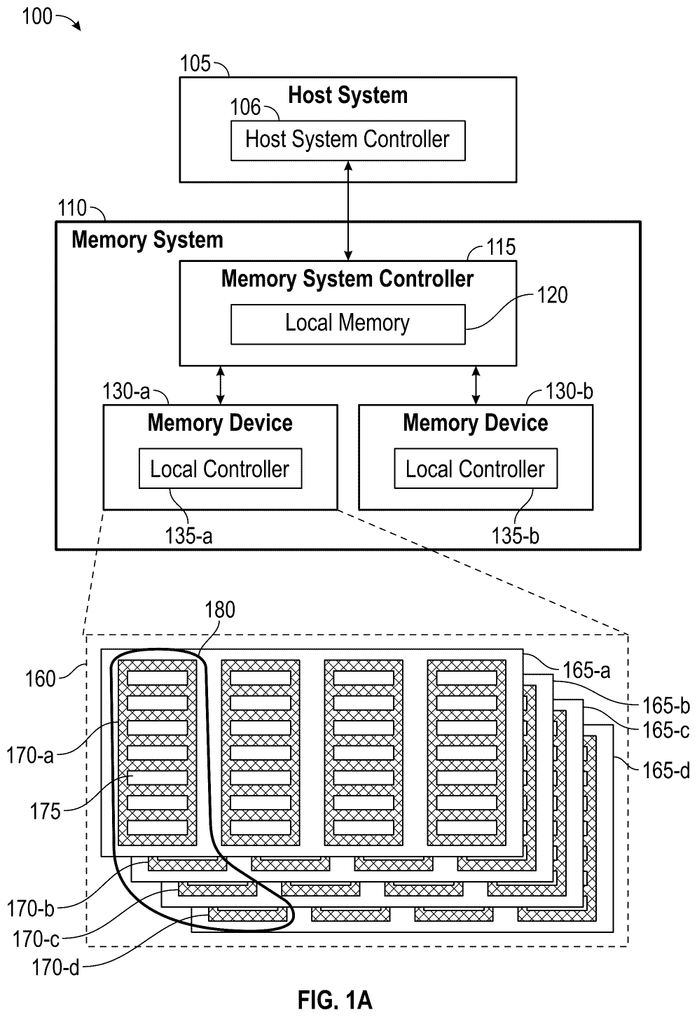

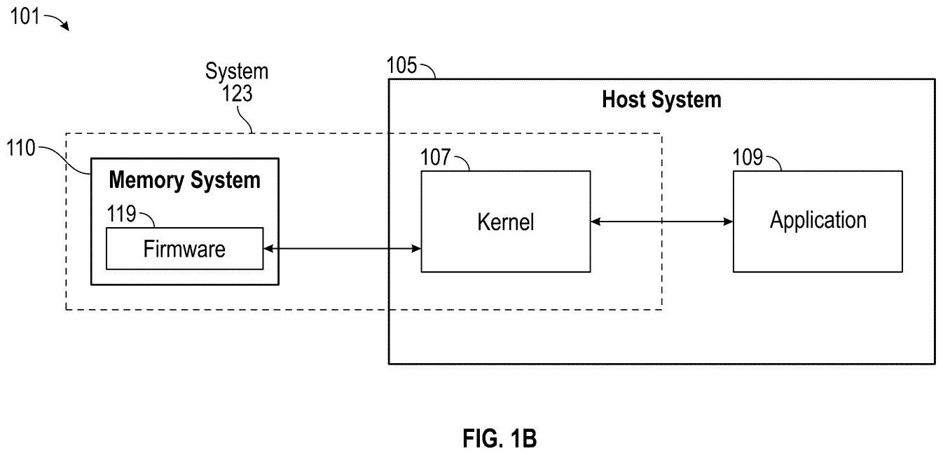

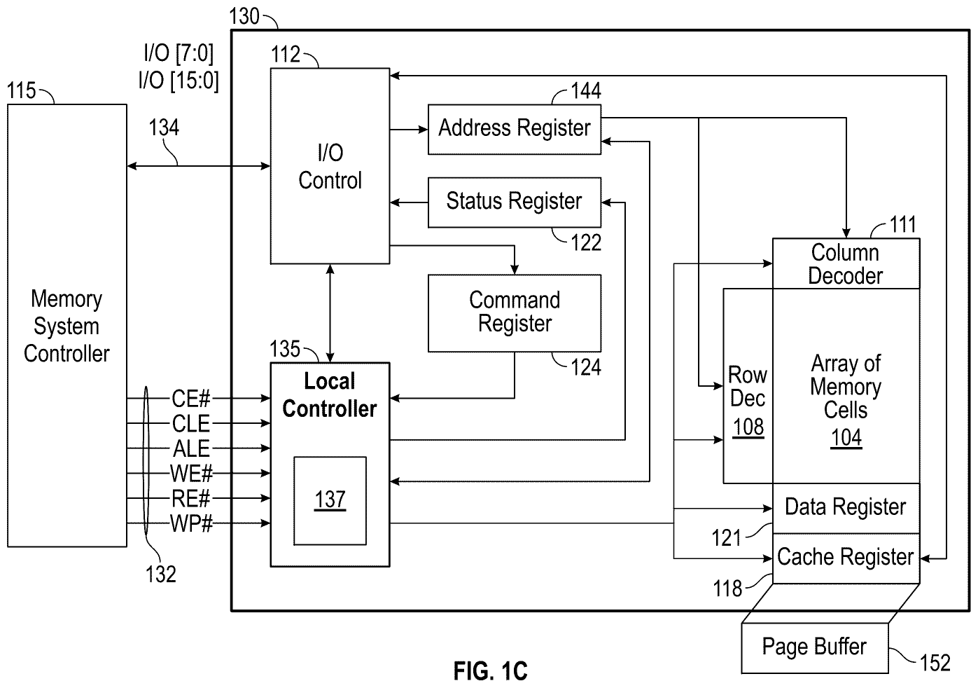

FIG. 1A illustrates an example of a system 100 that supports techniques for sensing RC time constant in real time in accordance with examples as disclosed herein. System 100 includes a host system 105 coupled with a memory system 110. System 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

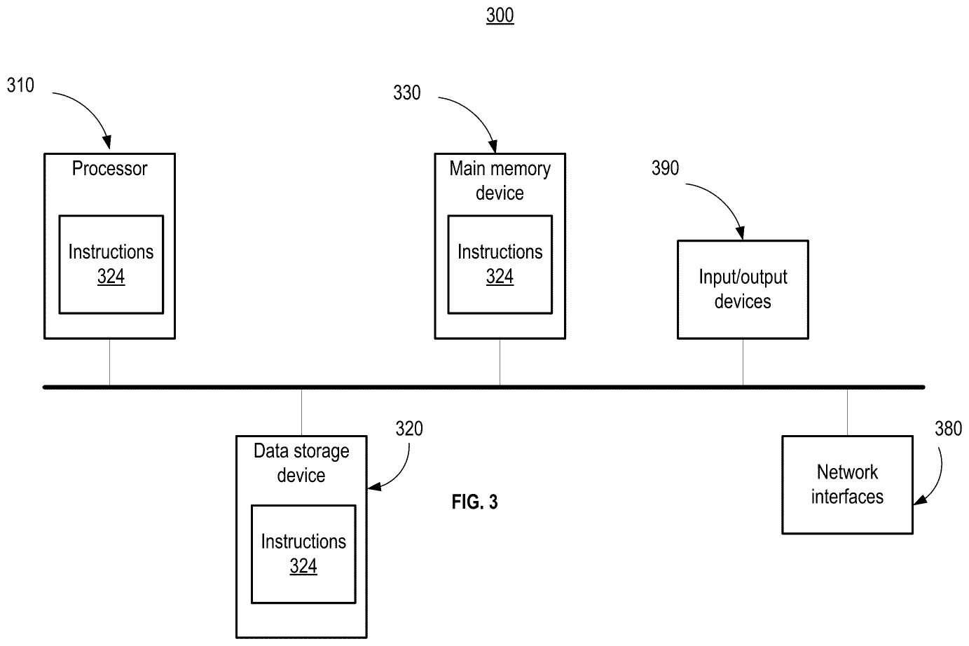

System 100 may include a host system 105, which may be coupled with memory system 110. In some examples, this coupling may include an interface with a host system controller 106, which may be an example of a controller or control component configured to cause host system 105 to perform various operations in accordance with examples as described herein. Host system 105 may include one or more devices and, in some cases, may include a processor chipset and a software stack executed by the processor chipset. Host system 105 may be implemented by, for example, an apparatus 300 shown in FIG. 3. For example, host system 105 may include an application configured for communicating with memory system 110 or a device therein. The processor chipset may include one or more cores, one or more caches (e.g., memory local to or included in host system 105), a memory controller (e.g., NVDIMM controller), and a storage protocol controller (e.g., peripheral component interconnect express (PCIe) controller, serial advanced technology attachment (SATA) controller). Host system 105 may use memory system 110, for example, to write data to memory system 110 and read data from memory system 110. Although one memory system 110 is shown in FIG. 1A, the host system 105 may be coupled with any quantity of memory systems 110.

Host system 105 may be coupled with memory system 110 via at least one physical host interface. Host system 105 and memory system 110 may, in some cases, be configured to communicate via a physical host interface using an associated protocol (e.g., to exchange or otherwise communicate control, address, data, and other signals between memory system 110 and host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a Graphical Double Data Rate (GDDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of host system 105 and a memory system controller 115 of memory system 110. In some examples, host system 105 may be coupled with memory system 110 (e.g., host system controller 106 may be coupled with memory system controller 115) via a respective physical host interface for each memory device 130 included in the memory system 110, or via a respective physical host interface for each type of memory device 130 included in memory system 110.

Memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1A, memory system 110 may include any quantity of memory devices 130. Further, if the memory system 110 includes more than one memory device 130, different memory devices 130 within the memory system 110 may include the same or different types of memory cells.

Memory system controller 115 may be coupled with and communicate with host system 105 (e.g., via the physical host interface) and may be an example of a controller or control component configured to cause memory system 110 to perform various operations in accordance with examples as described herein. Memory system controller 115 may also be coupled with and communicate with memory devices 130 to perform operations such as reading data, writing data, erasing data, or refreshing data at a memory device 130—among other such operations—which may generically be referred to as access operations. In some cases, memory system controller 115 may receive commands from the host system 105 and communicate with one or more memory devices 130 to execute such commands (e.g., at memory arrays within the one or more memory devices 130). For example, memory system controller 115 may receive commands or operations from host system 105 and may convert the commands or operations into instructions or appropriate commands to achieve the desired access of memory devices 130. In some cases, memory system controller 115 may exchange data with host system 105 and with one or more memory devices 130 (e.g., in response to or otherwise in association with commands from host system 105). For example, memory system controller 115 may convert responses (e.g., data packets or other signals) associated with the memory devices 130 into corresponding signals for the host system 105.

Memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from host system 105 and physical addresses (e.g., physical block addresses) associated with memory cells within memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to memory system controller 115. Memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

Memory system controller 115 may also include a local memory 120. In some cases, local memory 120 may include read-only memory (ROM) or other memory that may store operating code (e.g., executable instructions) executable by memory system controller 115 to perform functions ascribed herein to memory system controller 115. In some cases, local memory 120 may additionally, or alternatively, include static random access memory (SRAM) or other memory that may be used by memory system controller 115 for internal storage or calculations, for example, related to the functions ascribed herein to memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same semiconductor die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1A, a memory device 130-a may include a local controller 135-a and a memory device 130-b may include a local controller 135-b. In the examples illustrated in this disclosure (e.g., the example shown in FIG. 1C), local controller 135 is disposed on the same semiconductor die as the memory array (e.g., array 104); and a separate memory system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a memory system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of memory blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of memory blocks 170 and, in some cases, concurrent operations may be performed on different planes 165. For example, concurrent operations may be performed on memory cells within different blocks 170 so long as the different blocks 170 are in different planes 165. In some cases, an individual memory block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line). Example memory cells structures are shown in more detail below using illustrative schematics.

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, L2P (logical-to-physical) mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

System 100 may include any quantity of non-transitory computer readable media that support techniques for logical-to-physical table compression. For example, host system 105 (e.g., a host system controller 106), memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some cases, a memory system 110 may compress an L2P mapping to expand the quantity of physical addresses mapped by the L2P mapping. For example, if a set of consecutive entries of an uncompressed L2P mapping includes consecutive physical addresses, memory system 110 may compress the consecutive entries into a single entry which includes a starting physical address of the consecutive physical addresses. Additionally, memory system 110 may include an indication of a starting logical address corresponding to the starting physical address in the compressed entry. To identify a physical address within the compressed entry, memory system 110 may determine an offset between a logical address corresponding to the physical address (e.g., a logical address included in a read command for data stored at the physical address) and the starting physical address using the indication, and may apply the offset to the starting physical address to determine the physical address. Compressing the L2P mapping may allow the L2P mapping to cover an expanded range of physical address space without increasing the size of the L2P mapping.

FIG. 1B illustrates an example of a system diagram 101 that illustrates communication between host system 105 and memory system 110 via using a kernel and firmware, in accordance with examples as disclosed herein. System diagram 101 may include a memory system 110, a kernel 107, and an application 109. The memory system 110 may include a firmware 119. Firmware 119 may be implemented by a controller and/or other circuitry of the memory system (e.g., memory system controller 115 and/or local controllers 135 shown in FIG. 1A). In some examples, a system 123 as described herein may include memory system 110 and kernel 107. Additionally, a host system 105 may include kernel 107 and the application 109.

As described above, memory system 110 may include multiple memory devices, including non-volatile memory devices and volatile memory devices (e.g., local memory 120), configured to store and retrieve data. Firmware 119 may refer to software stored within a memory array within memory system 110 (e.g., a non-volatile memory device within the memory system 110) and/or a local memory 120 as shown in FIG. 1A. Firmware 119 may provide low-level control functions for the memory system 110. For example, firmware 119 may function as an interface between the memory system 110 and other components of the system 123, and host system 105 may issue access operations to memory system 110 by interfacing with firmware 119. In some examples, firmware 119 may be or be included within or implemented by a memory system controller 115, as described herein with reference to FIG. 1A. In some examples, memory system 110 may store a logical-to-physical mapping that maps logical addresses to physical addresses within a non-volatile memory device (e.g., in a logical-to-physical table). To perform a memory access operation, memory system 110 may move a portion of the logical-to-physical mapping corresponding to one or more logical addresses (e.g., indicated by kernel 107) from the non-volatile memory device to a volatile memory device.

Kernel 107 may function as an interface between host system 105 and components associated with host system 105, such as an operating system of host system 105. Additionally, kernel 107 may perform resource allocation and file management, among other operations, for host system 105. For example, an application 109 running within host system 105 may access information stored within memory system 110 by issuing commands to kernel 107, which may indicate files to be accessed. Kernel 107 may store mapping information associated with the files. For example, a file may be associated with a file name, and may correspond to a range of logical block addresses. Kernel 107 may store mapping information (e.g., a mapping table) that may track logical block addresses corresponding to files of host system 105. In some examples, application 109 may issue an access command to kernel 107 indicating a file name, and offset, and a length associated with a file to be accessed, and kernel 107 may retrieve a one or more logical block addresses corresponding to the file to be accessed. Kernel 107 may then communicate with firmware 119 to indicate the one or more logical block addresses to memory system 110, and memory system 110 may perform an access operation based on the one or more logical block addresses. Memory system 110 may communicate the accessed information to kernel 107 (e.g., via the firmware 119).

In some examples, kernel 107 may communicate with to firmware 119 using information units (e.g., UFS protocol information units (UPIUs)). For example, kernel 107 may issue or receive commands, responses, data, or other information via information units exchanged with the firmware 119. An information unit may refer to a data packet that may contain a header segment and one or more transaction specific fields. In some examples, an information unit may additionally include one or more extended header segments, one or more data segments, or a combination thereof. The header segments of an information unit may indicate information associated with a destination for the information unit, a source of the information unit, a function request, whether additional data or parameters are to be transmitted, whether the additional data or parameters are included within the information unit or to be sent in a following information unit, or any combination thereof. The transaction specific fields may be used for additional fields depending on the operation associated with the information unit. The data segments may be used to include data to be transferred from a device to another.

In some examples, a command information unit (e.g., a command UPIU) may be an example of an information unit associated with the transmission of a command (e.g., an SCSI command) and may indicate a device to perform some operation indicated by the command information unit. For example, the command information unit may include a block descriptor (e.g., a command descriptor block) which may indicate information related to the operation indicated by the command information unit. In some examples, kernel 107 may transfer a command information unit to memory system 110 to indicate memory system 110 of an operation to be performed by memory system 110.

In some examples, to perform an access operation, memory system 110 may load a L2P mapping associated with information to be accessed. For example, memory system 110 may transfer a portion of a logical-to-physical mapping associated with the information to be accessed from a non-volatile memory device of memory system 110 (e.g., NAND memory) to a volatile memory device (e.g., an SRAM) of the memory system 110. In another example, host system 105 may notify memory system 110 of a logical block address range corresponding to an upcoming access operation (e.g., prior to issuing an access command). Memory system 110 may use the logical block address range to load (e.g., pre-load, pre-fetch) an associated portion of a L2P mapping (e.g., from a non-volatile memory device to a volatile memory device) prior to receiving an access command that indicates memory system 110 to perform the access operation. Accordingly, after host system 105 issues the access command, memory system 110 may issue a response to host system 105 faster as memory system 110 has already loaded relevant portions of the L2P mapping associated with the access operation.

The above description of the system diagram 101 are illustrative examples of communication between host system 105 and memory system 110 by using a kernel 107, application 109, and firmware 119. It is understood that additional ways of communication, including function calls, commands, responses, messages, etc. can be implemented using host system 105 and memory system 110, and/or additional systems or components.

FIG. 1C is a simplified block diagram of a memory device 130 in communication with a memory system controller 115 of a memory system (e.g., the memory system 110 of FIGS. 1A and 1B), according to an embodiment. As shown in FIG. 0.1C and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1C) of at least a portion of the array of memory cells 104 are capable of being programmed to one of at least two target data states for storing any number of bits of information.

With continued reference to FIG. 1C, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external memory system controller 115, i.e., the local controller 135 is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the memory system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to memory system controller 115.

As shown in FIG. 1C, memory device 130 receives various control signals via local controller 135 from memory system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the memory system controller 115 over a multiplexed input/output (I/O) bus 134 and outputs data to the memory system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 144. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1C has been simplified. It should be recognized that the functionality of the various block components described with reference to FIG. 1C may not necessarily be segregated to distinct components or component portions of an integrated circuit device. For example, a single component or component portion of an integrated circuit device could be adapted to perform the functionality of more than one block component of FIG. 1C. Alternatively, one or more components or component portions of an integrated circuit device could be combined to perform the functionality of a single block component of FIG. 1C. Additionally, while specific I/O pins are described in accordance with popular conventions for receipt and output of the various signals, it is noted that other combinations or numbers of I/O pins (or other I/O node structures) can be used in the various embodiments.

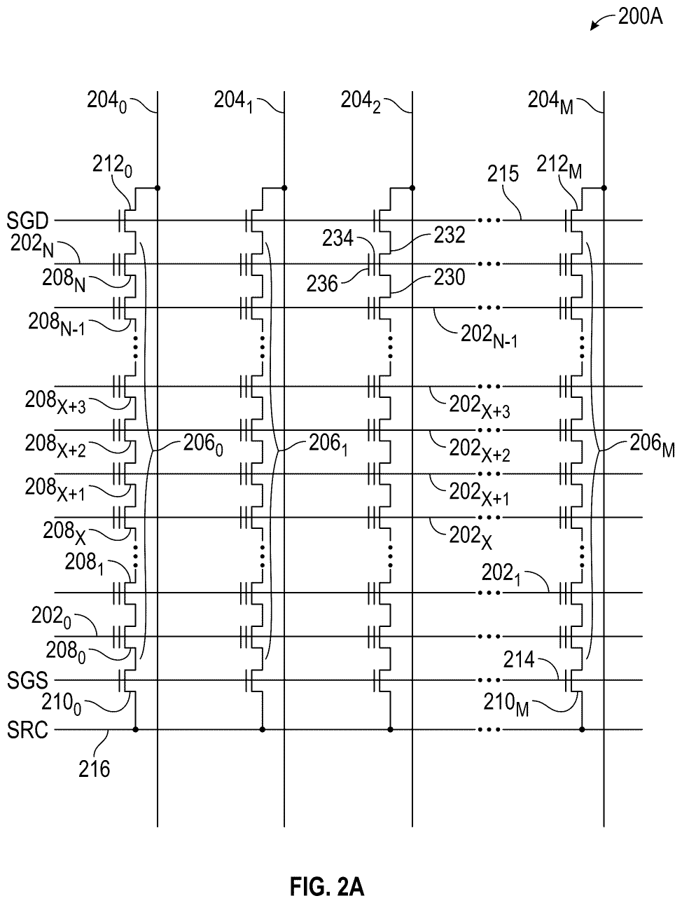

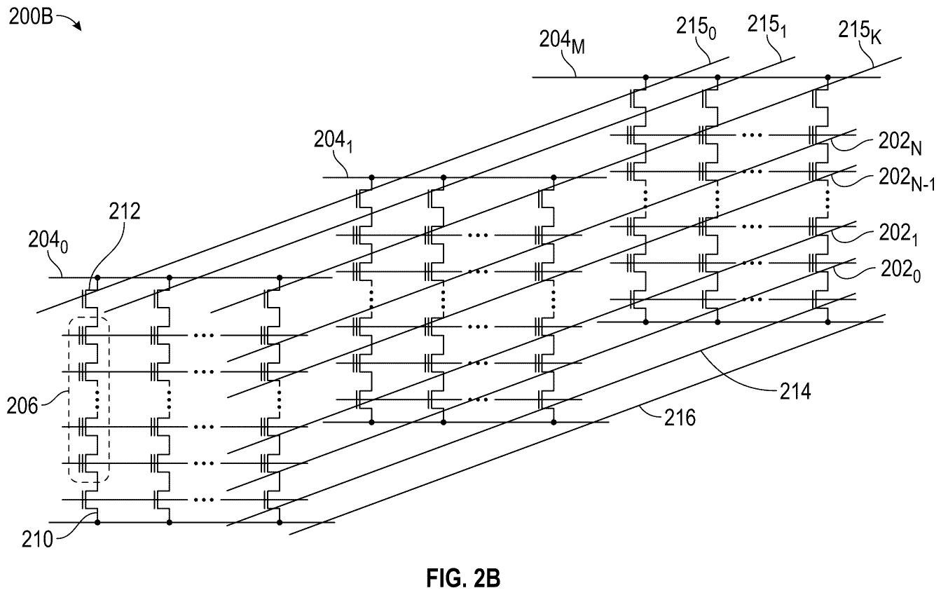

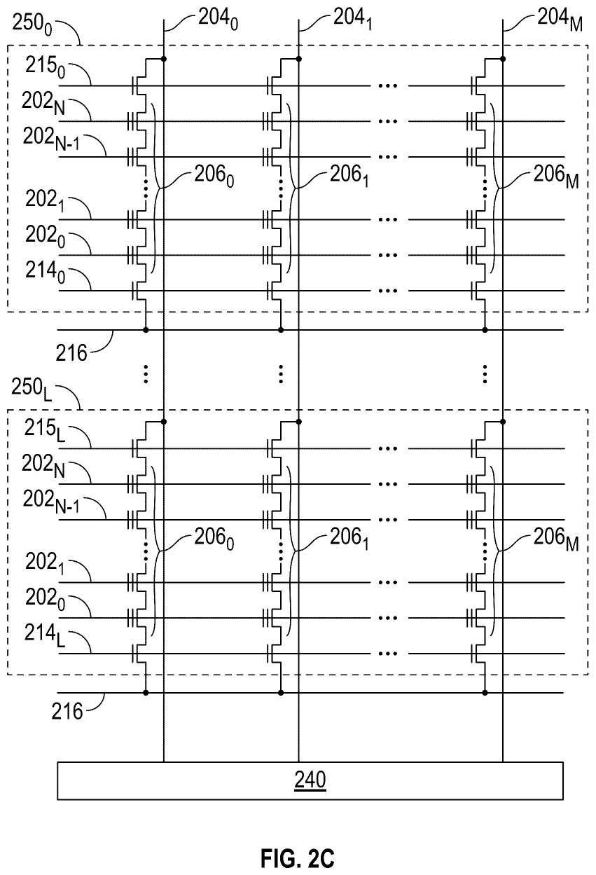

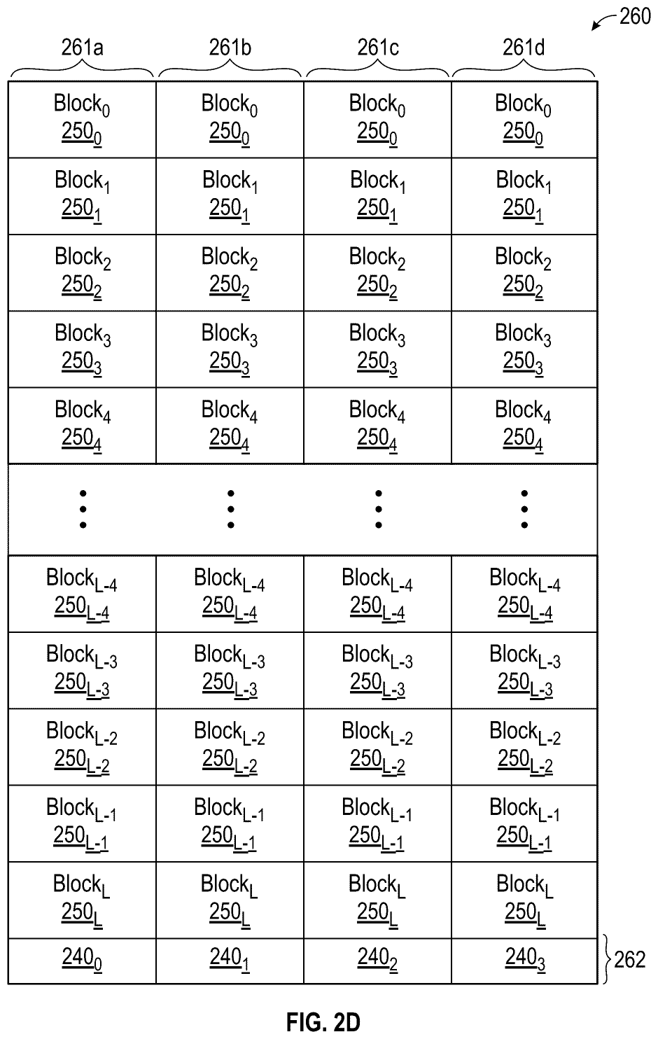

FIG. 2A-2B are example schematics of portions of an array of memory cells 200A, such as a NAND memory array. Array of memory cells 200A may be an example of memory array 104 of a memory device 130 as described with reference to FIG. 1C according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to select line 214.

The drain of each select gate 212 can be connected to bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device described with reference to FIG. 1B, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

As described above, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204.

FIG. 2D is a block schematic of a portion of an example array of memory cells 260. Array of memory cells 260 can be used as array 104 in a memory device 130 described with reference to FIG. 1C. The array of memory cells 260 is depicted as having four memory planes 261 (e.g., memory planes 261a-261d). Each of the memory planes 261 can correspond to planes 165 depicted in FIG. 1A. Each memory plane 261 can be in communication with a respective buffer portion 240, which can collectively form a page buffer 262. Page buffer 262 may be used to implement page buffer 152 shown in FIG. 1C. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

With continued reference to FIGS. 1C and 2A-2C, during a true erase operation (during which memory cells are actually being erased), the local controller 135 (e.g., using an erase operation manager 137) can cause a common source voltage line, e.g., the SRC 216 (FIG. 2A), to be ramped to an erase voltage (VERA) with an erase pulse while the select gates 210₀ to 210_{M} (SGS transistors) are turned on. Ramping to this high bias erase voltage, and the subsequent recovery from this voltage ramping, may take a significant amount of time. Concurrently, the erase operation manager 137 can cause the select gates 212₀ to 212_{M} (FIG. 2A) to be turned off to enable the drains of the select gates 212₀ to 212_{M} to float, which causes the bit lines 204₀ to 204_{M} to also float. Further, the erase operation manager 137 can couple the word lines 202 (FIG. 2A) to ground, e.g., zero volts, or retain the word lines 202 at a low voltage. This set of voltage levels at the memory array 200A can create an erase potential that causes the memory cells 208₀ to 208_{N} to be erased, e.g., forces electrons to exit through a body of each memory cell and out the floating bit lines 204₀ to 204_{M}. In other embodiments, the reverse can be done so the select gates 210₀ to 210_{M} are turned off, causing the SRC line 216 to float while the voltage of the bit lines are ramped to Vera while the select gates 212₀ to 212_{M} are turned on. As mentioned earlier, in 3D NAND, one of the channel region, pillar, or bit line can also be ramped up in voltage to cause erasure of attached memory cells. Thus, for simplicity herein, reference to “memory line” should be understood to make reference to any of the SRC line or bit lines in 2D NAND or to any of channel, pillar, or bit lines in 3D NAND. In some embodiments, one or more sub-blocks, to include a physical block, of memory cells are erased during the same true erase operation. A block of memory cells can be generally understood to include four or more sub-blocks, wherein each sub-block includes a separate string of memory cells.

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1A-10B, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system (e.g., host system 105 shown in FIG. 1A) that includes, is coupled to, or utilizes a memory system (e.g., memory system 110 of FIG. 1A). Apparatus 300 can be used to perform operations of a controller (e.g., to execute an operating system to perform operations corresponding to host system controller 106 and/or local controller 135 of FIG. 1A).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., host system controller 106 and/or local controller 135 of FIG. 1A). The computer program instructions 324 may be stored in data storage device 320, or other computer-readable medium, and loaded into main memory device 330 when execution of the computer program instructions is desired. For example, processor 310 may be used to implement one or more components and systems described herein, such as host system controller 106 and/or local controller 135 (shown in FIG. 1A). Thus, the method steps of at least some of FIGS. 1A-10B can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1A-10B. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using memory system 110 (FIG. 1A) described herein. In some examples, data storage device 320 and main memory device 330 may include one or more memory devices 130 (FIG. 1A).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

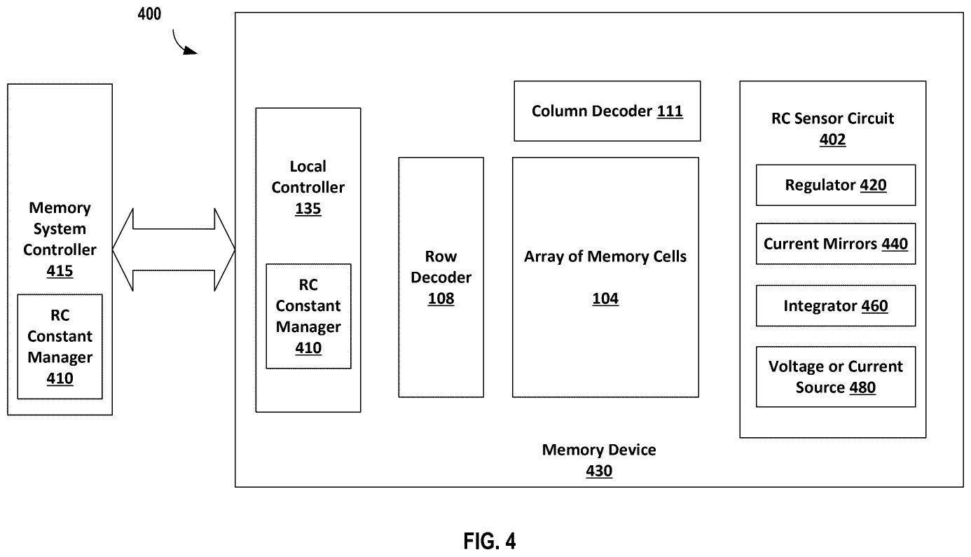

FIG. 4 is a block diagram of an example memory system 400 that supports techniques for sensing RC time constant of a circuit line in real time in accordance with examples as disclosed herein. As shown in FIG. 4, memory system 400 corresponds to memory system 110 described above. Similar to memory system 110, system 400 also includes a memory system controller 415 that communicates with memory device 430. Controller 415 and memory device 430 can be the same or substantially similar to controller 115 and memory device 130 described above. For example, memory device 430 may include some or all of the same components or functional blocks (e.g., local controller 135, row decoder 108, array of memory cells 104, and column decoder 111) as the memory device 130 described above. These blocks are thus not repeatedly described.

In some embodiments, memory device 430 includes an RC sensor circuit 402 configured to drive a circuit line (e.g., a word line). The RC sensor circuit 402 can output digital data, which is used to measure an RC time constant of the circuit line. As shown in FIG. 4, in one example, RC sensor circuit 402 includes a regulator 420, which can be configured to drive a circuit line having an RC time constant. It further includes one or more current mirrors 440 coupled to regulator 420. Current mirrors 440 are configured to obtain a representative copy of the current of the circuit line. RC sensor circuit 402 further includes an integrator 460, which integrates the representative copy of the current of the circuit line for a plurality of time intervals. Based on the integration results, digital data output can be provided to calculate the RC time constant of the circuit line. In some examples, RC sensor circuit 402 may also include a voltage or current source 480, which can be used in measuring the representative copy of the current of the circuit line and optionally obtain a lookup table or an equivalent thereof. Regulator 420, current mirrors 440, integrator 460, and voltage or current source 480 are described in greater detail below.

In FIG. 4, RC sensor circuit 402 is shown as a separate block from other components of memory device 430. It can also be integrated or grouped into other components. For example, it may be a part of the local controller 135, array of the memory cells 104, or one or both of decoders 108 and 111. In some examples, one or both of local controller 135 and memory system controller 415 may also include an RC constant manager 410. RC constant manager 410 can be used to manage and/or control the operation of the RC sensor circuit 402. For example, it may be a part of the controller 415 or 135 such that RC sensor circuit 402 receives commands or instructions from one or both controllers to sense the RC time constant in real time (e.g., while the array of memory cells 104 is being accessed by, for example, either a read operation or a program operation). The RC constant manager 410 is described in greater detail below.

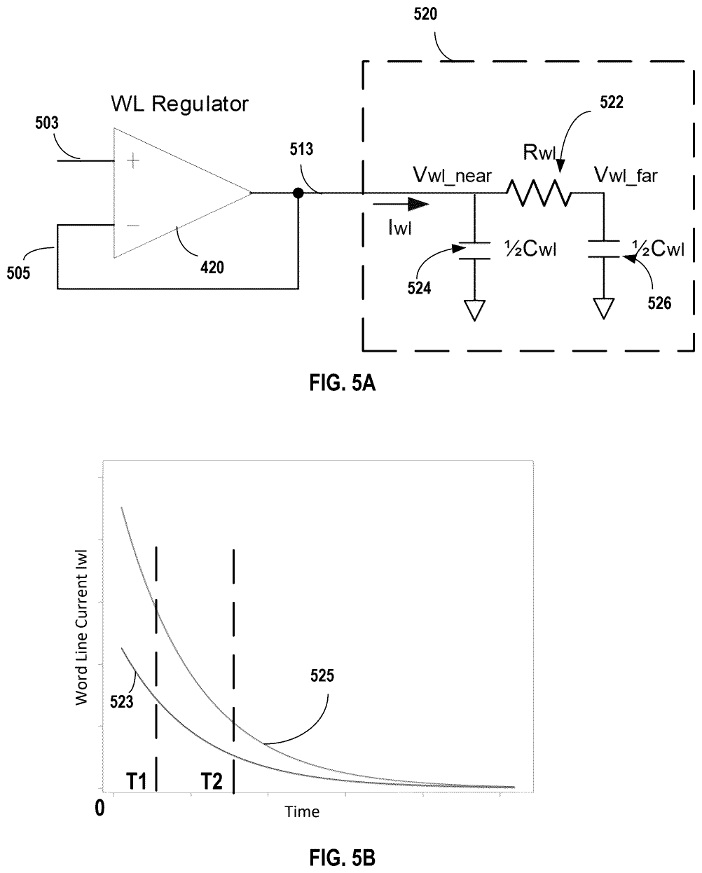

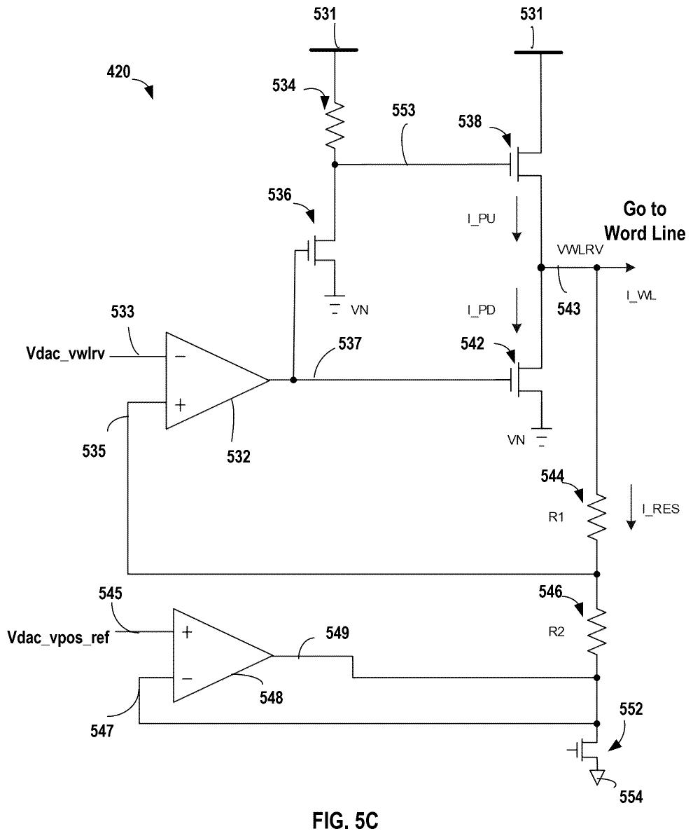

Turning to the first component of the RC sensor circuit 402 and using a word line as an example of a circuit line, FIG. 5A is a schematic of an example word line regulator 420 driving a word line 520, in accordance with examples as disclosed herein. FIG. 5A shows a word line regulator 420 configured such that its output terminal 513 is connected to the negative input terminal 505. Its positive input terminal 503 may receive a reference voltage signal for generating a driving voltage at the output terminal 513. Output terminal 513 of regulator 420 is coupled to word line 520. Word line 520 is shown by a simplified equivalent circuit with a resistor 522 (denoted by R_{wl}) coupled between two capacitors 524 and 526 (denoted by ½C_{wl}). Each of the capacitors 524 and 526 represents a half of the capacitance of the word line 520. And the resistor 522 represents the resistance of the word line 520. The word line 520 has a near end and a far end. The near end is coupled directly to the output terminal 513 of the regulator 420 for receiving the driving voltage signal. The far end of the word line 520 represents a position that is relatively far away from the output terminal 513 of regulator 420. The far end may be, for example, at a control gate (e.g., control gate 236 shown in FIG. 2A) of a particular memory cell. The particular memory cell may be located far away from the output terminal 513 of the regulator 420 and is typically inaccessible for measurement of the voltage. As shown in FIG. 5A, therefore, for a word line 520, there is a near-end voltage (denoted by V_{wl_near}) and a far-end voltage (denoted by V_{wl_far}). To measure the RC time constant of the word line 520, the far-end voltage should be used but it is inaccessible. Thus, the techniques described herein measure the word line current (denoted by I_{wl}), or a representative copy of it, to determine the RC time constant of the word line 520.

FIG. 5B are example relations between the word line current and time for a same time constant with different resistance and capacitance values, in accordance with examples as disclosed herein. In FIG. 5B, the horizontal axis represents time, and the vertical axis represents word line current (denoted by I_{wl}). Curve 523 and curve 525 both show that the word line current becomes smaller and should approach zero given sufficient time. Curve 523 and curve 525 may represent two different word lines having the same RC time constant. For example, the word line corresponding to curve 523 may have a high resistance (e.g., 200K ohm) and a low capacitance (e.g., 10 pF); while the word line corresponding to curve 525 may have a low resistance (e.g., 100K ohm) and high capacitance (e.g. 20 pF). The RC time constants for the two word lines thus are the same. But the word line currents I_{wl} for these two word lines are different, as shown in FIG. 5B (e.g., the word line corresponding to curve 525 may have a higher word line current at any given time).

To measure the word line RC time constant, in some examples, two or more time intervals are selected. For example, in FIG. 5B, a first time interval is from the zero time point to T1, and the second time interval is from the zero time point to T2. Next, the integration of the word line current I_{wl} is calculated for the two time intervals (i.e., from 0 to T1, and from 0 to T2). The integration of the current results in a total charge of the time interval. Thus, integration of word line current I_{wl} from time 0 to time T1 results in a charge Q₁; and integration of word line current I_{wl} from time 0 to time T2 results in a charge Q₂. The ratio of the charges Q₁ and Q₂ can be calculated as the equation [1] below.

$$\frac{{Q}_{1}}{{Q}_{2}} = \frac{1 - {e}^{- T 1 / τ}}{1 - {e}^{- T 2 / τ}} \qquad [ 1 ]$$

In the above equation [1], Q1 and Q2 denote charges obtained from integration of the word line current Iwi over the two time intervals T1 and T2 (both from time 0); e denotes the Euler's number or the natural base and is an irrational number of 2.718281828459 . . . ; r represents the RC time constant of the word line. Therefore, by measuring the word line current, and then obtaining the charges over two or more time intervals, the RC time constant T can be calculated. For the two word lines corresponding to the two curves 523 and 525 in FIG. 5B, the RC time constant is the same despite the word line current is different.

As described above, by measuring the word line current, rather than the inaccessible far-end word line voltage, the RC time constant of the word line can be calculated. The measurement of the word line current, in some examples, needs to be accurate (e.g., with an inaccuracy less than 1%). The accurate measurement of the word line current translates to an accurate measurement of the RC time constant (e.g., if the inaccuracy of word line current measurement is less than 1%, the inaccuracy of the RC time constant can be less than 3%). Furthermore, the measurement speed needs to be fast in order to realize the real-time measurement. For instance, the speed of RC time constant measurement may need to be fast enough such that the measurement is completed within 0.5 μs, or within any time requirement for real-time operation. There exist certain challenges of measuring the word line current. For example, it cannot be directly measured and therefore current mirrors are used to obtain a representative copy of the word line current, and the representation copy is measured. As a result, the current mirrors (e.g., current mirrors 440) need to be configured such that the representative copy of the current is sufficiently accurate and matching with the word line current. Additionally, the integrator (e.g., integrator 460) needs to be configured such that the word line current can be converted from analog values to digital values for calculating the charge ratio and for obtaining the RC time constant. Examples of the circuits used for the RC sensor circuit 402 are described below in greater detail.

FIG. 5C is a schematic of an example word line regulator 420, in accordance with examples as disclosed herein. As illustrated in FIG. 5C, regulator 420 may include one or more operational amplifiers (e.g., op-amps 532 and 548), a resistor divider (e.g., including resistors 544 and 546 connected in series) coupled to the one or more operational amplifiers, and a plurality of transistors coupled to the one or more op-amps. The op-amps 532 and 548 receive certain reference voltages as input signals. For example, op-amp 532 receives a reference voltage signal denoted by V_{dac_vwlrv} at its negative input terminal 533. Its positive input terminal 535 is connected to a node between resistors 544 and 546. The resistor divider includes resistor 544 (denoted as R₁) and resistor 546 (denoted as R₂), which are configured to provide a resistor divider current (denoted by Iᵣₑₛ or I_{_RES}). In some examples, another op-amp 548 is used. Op-amp 548 receives another reference voltage denoted by V_{dac_vpos_ref} at its positive input terminal 545. Its negative input terminal 547 is connected to a node between resistor 546 (denoted as R₂) and a transistor 552. This node is also connected to the output terminal 549 of the op-amp 548. Using the op-amp 548, and with a proper reference voltage value of V_{dac_vpos_ref}, the voltage of output terminal 549 of op-amp 548 can be set at any value, including a negative voltage value. If the voltage of output terminal 549 is set to be a negative voltage, transistor 552 is turned off, such that the resistor divider of the regulator circuit is disconnected from the electrical ground 554, which is usually at 0V. Therefore, using the op-amp 548, the bottom node of resistor 546 (denoted by R₂) can be set at a negative voltage (compared to a 0V at the electrical ground 554), thereby expanding the operational range of the regulator 420.

FIG. 5C further shows a plurality of transistors 536, 538, 542, and another resistor 534. For illustration purposes, the transistors 536, 538, and 542 are shown as NMOS transistors (N-type metal-oxide-semiconductor). But it is understood that other types of transistors may also be used (e.g., PMOS transistors, bipolar transistors, etc.). The output terminal 537 of op-amp 532 is coupled to the gate terminals of transistor 536, and the gate terminal of transistor 542. The source terminal of transistor 536 may be connected to an electrical ground denoted by V_{N}. The drain terminal of transistor 536 may be coupled to a first terminal 553 of resistor 534, and the second terminal of resistor 534 may be coupled to a power supply 531. The drain terminal of transistor 538 may also be coupled to power supply 531, the gate terminal of transistor 538 is coupled to the first terminal 553 of resistor 534. The current generated by transistor 538 is referred to as the pull-up current (denoted as Tₚ or I_{_PU}). The source terminal of transistor 538 is coupled to the drain terminal of transistor 542. The source terminal of transistor 542 is coupled to the electrical ground denoted by V_{N}. The drain terminal of the transistor 542 is the output terminal 543 of regulator 420, and is also coupled to the word line being driven by regulator 420. The output terminal 543 is also coupled to the resistor divider including the resistors 544 and 546 as shown in FIG. 5C. Therefore, the current generated by, or passing through, transistor 542 is referred to as the pull-down current (denoted as I_{pd} or I_{_PD}). The current passing through the resistor divider (including resistors 544 and 546) is referred to as the resistor divider current (denoted by Iᵣₑₛ or I_{_RES}).

Based on the configuration of FIG. 5C, the word line current (denoted by I_{wl}) is thus a function of the pull-up current, the pull-down current, and the resistor divider current, as described in the below equation [2].

$${I}_{wl} = {I}_{pu} - {I}_{pd} - {I}_{res} \qquad [ 2 ]$$

The word line voltage (denoted by V_{wlrv}) can also be calculated based on the below equation [3].

$${V}_{wlrv} = {V}_{dac \_ vwlrv} ( \frac{{R}_{1}}{{R}_{2}} + 1 ) - {V}_{dac \_ vpos \_ ref} \frac{{R}_{1}}{{R}_{2}} \qquad [ 3 ]$$

In the above equation [3], V_{dac_vwlrv} denotes the reference voltage provided to the input terminal of op-amp 532, and V_{dac_vpos_ref} denotes the reference voltage provided to the input terminal of op-amp 548. R₁ and R₂ denote the resistances of resistors 544 and 546 used in the resistor divider. Therefore, by controlling the two reference voltages V_{dac_vwlrv} and V_{dac_vpos_ref}, and setting the proper values R₁ and R₂ of the resistors 544 and 546, a target word line voltage V_{wlrv} can be obtained. The word line current I_{wl}, which is the net current charging the word line, can then be calculated based on the equation [2] above.

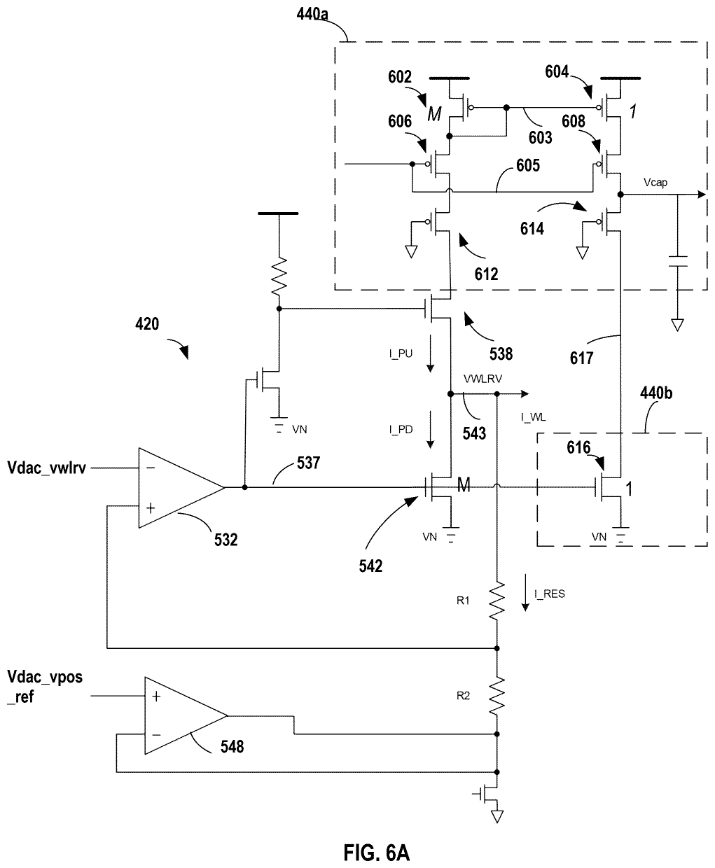

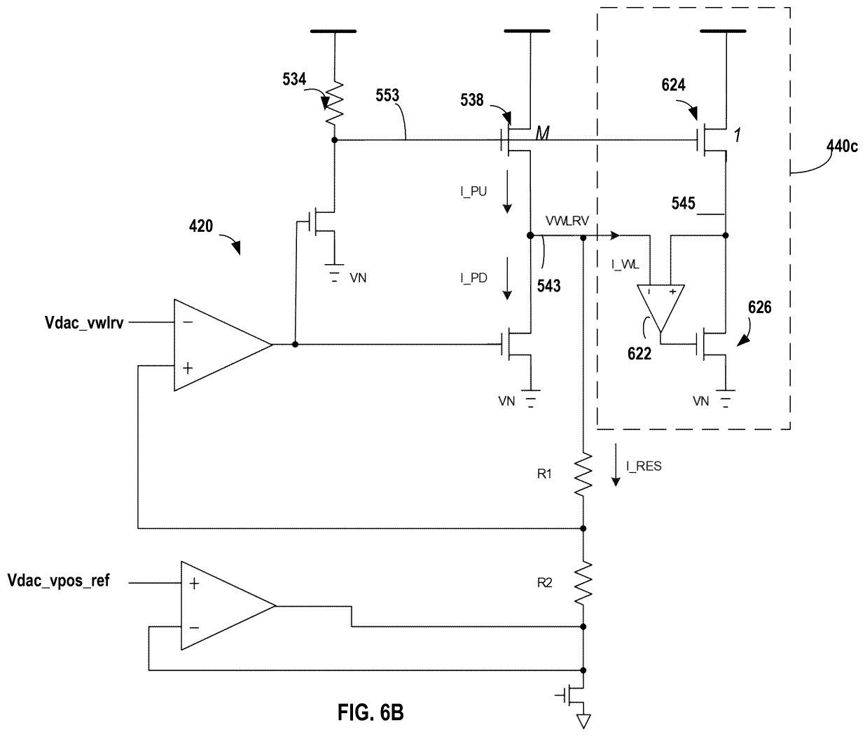

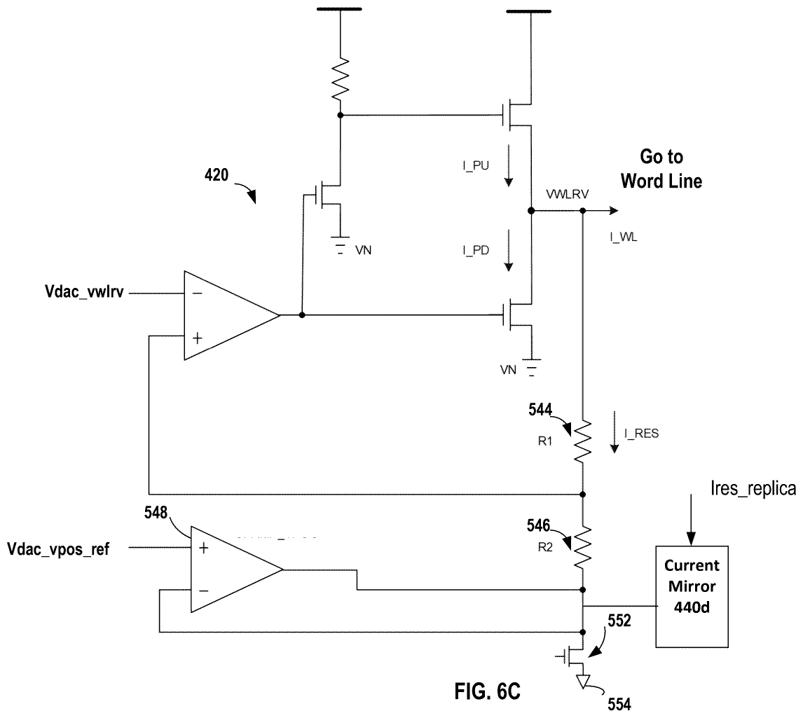

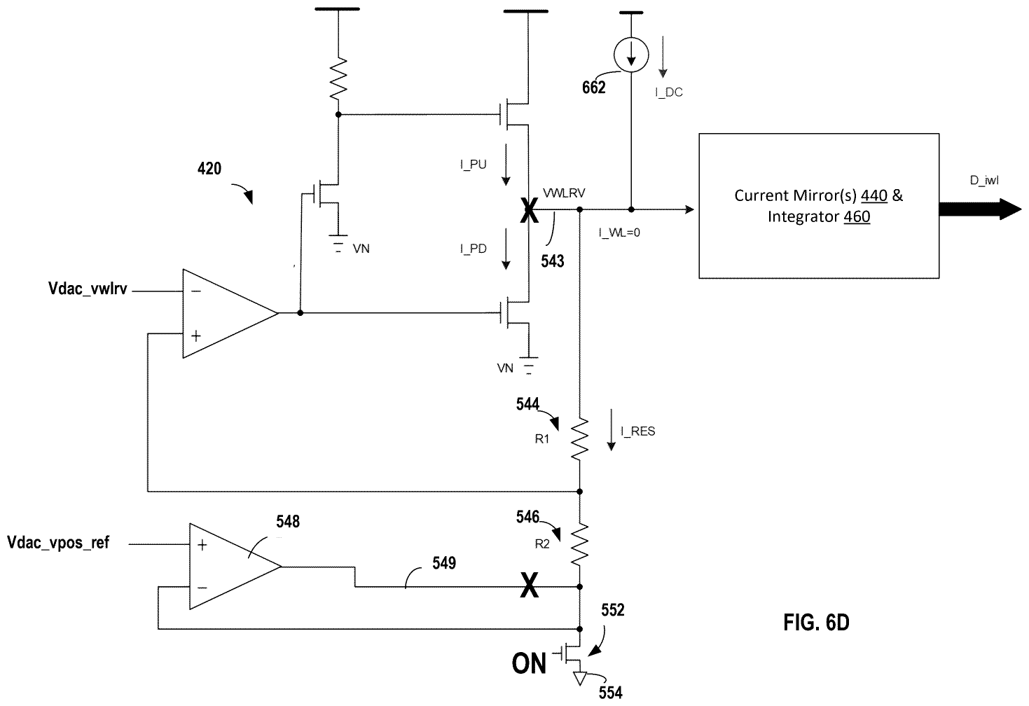

As described above, the word line current usually cannot be measured directly because direct measurement may change the current used for driving the word line, and therefore may interfere with an operation (e.g., a read or program operation). Thus, the word line current may need to be “mirrored” out, which means to obtain a representative copy of it for measurement. Current mirrors are frequently used for obtaining representative copies of currents. FIG. 6A is a schematic of an example word line regulator 420 and example current mirrors 440a-440b for obtaining representative copies of pull-up and pull-down currents, respectively, in accordance with examples as disclosed herein. Regulator 420 is the same as described above in connection with FIG. 5C. Regulator 420 may generate a pull-up current denoted by Iₚᵤ (or I_{_PU}) a pull down current denoted by I_{pd} (or I_{_PD}) and a resistor divider current denoted by Iᵣₑₛ (or I_{_RES}). The word line current (denoted by I_{wl}) is calculated based on the pull-up current, the pull-down current, and the resistor divider current. Therefore, if a representative copy of each of the pull-up current, the pull-down current, and the resistor divider current can be obtained, the representative copy of the word line current can be obtained.

With reference to FIG. 6A, a current mirror 440a can be configured to obtain a representative copy of a pull-up current generated by the regulator. As shown in FIG. 6A, current mirror 440a is coupled to regulator 420 to obtain the pull-up current (Iₚᵤ). Current mirror 440a includes transistors to replicate or “mirror” the current flowing in one branch of the current mirror 440a to another branch of the current mirror 440a. As one example shown in FIG. 6A, current mirror 440a includes a left branch having one or more transistors such as transistors 602, 606, and 612; and a right branch having corresponding one or more transistors such as transistors 604, 608, and 614. PMOS transistors are used for illustration, but other types of transistors may also be used. In the left branch of current mirror 440a, the drain terminal of transistor 612 is coupled with the drain terminal of transistor 538 of the regulator 420; the gate terminal of transistor 612 is connected to electrical ground (therefore, the PMOS transistor 612 is turned on); and the source terminal of transistor 612 is coupled with the drain terminal of transistor 606. The gate terminal of transistor 606 may be connected to an external biasing circuit (not shown) to receive a biasing voltage so that the current mirror 440a has a proper operating point. The source terminal of transistor 606 is coupled with the drain terminal of transistor 602; the gate terminal and the drain terminal of transistor 602 are coupled together and are coupled with the gate terminal of the transistor 604 of the right branch; and the source terminal of transistor 602 is coupled with the power supply. Thus, the left branch includes three transistors 612, 606, and 602. The current flowing through the left branch of the first current mirror 440a is the pull-up current (denoted by Iₚᵤ).

Correspondingly, in the right branch of the current mirror 440a, transistors 604, 608, and 614 are configured to replicate the pull-up current in the left branch. Source terminal of transistor 604 is coupled with the power supply; gate terminal of transistor 604 is coupled with the gate terminal and the drain terminal of transistor 602 in the left branch (forming a current mirror structure); and the drain terminal of transistor 604 is coupled with the source terminal of transistor 608. The gate terminal of transistor 608 is coupled with the gate terminal of transistor 606 in the left branch, therefore, transistor 608 also receives the biasing voltage from a biasing circuit. The drain terminal of transistor 608 is coupled with the source terminal of transistor 614. In some examples, an optional capacitor (denoted V_{cap}) is also present at the drain terminal of transistor 608/source terminal of transistor 614. The gate terminal of transistor 614 is coupled to electrical ground (so transistor 614 is turned on). The pair of transistors 602 and 604 have their gate terminal coupled together and so form a current mirror pair; and the pair of transistors 606 and 608 have their gate terminals coupled together and both receiving a biasing voltage, therefore they form a biasing pair. The pull-up current Iₚᵤ flowing through the left branch is therefore replicated or “mirrored” to the right branch.

In some examples, the pair of transistors 602 and 604 have an M:1 ratio in terms of their area (e.g., if transistors 602 and 604 have the same length, then their widths have a M:1 ratio), where M can be a positive number. The representative copy of pull-up current in the right branch is thus 1/M of the pull-up current in the left branch. For measurement purposes, the representative copy of the pull up current does not need to be as big as the true pull-up current, as long as the M:1 ratio is taking into account in the subsequent calculation of RC time constant. Using smaller current in the representative copy of the pull-up current can therefore reduce power consumption. In the above description of the current mirror 440a, the right branch, or a part of it, may be referred to as the pull-up replica circuit.

With continued reference to FIG. 6A, a current mirror 440b can be configured to obtain a representative copy of the pull-down current from regulator 420. As shown in FIG. 6A, in one example, current mirror 440b includes a transistor 616, which is an NMOS transistor. Transistor 616 has its gate terminal coupled with the gate terminal of transistor 542, which generates the pull-down current (I_{pd}). Transistor 616 has its source terminal coupled to electrical ground and its drain terminal coupled to the right branch of the current mirror 440a. Therefore, transistor 616 operates as a second current mirror to replicate or “mirror” the pull-down current flowing through transistor 542. Similarly, transistors 542 and 616 have an M:1 ratio in terms of their areas (e.g., if transistors 542 and 616 have the same length, then their widths have a M:1 ratio), where M can be a positive number. The representative copy of pull-down current in current mirror 440b is thus 1/M of the pull-down current in the regulator 420. For measurement purposes, the representative copy of the pull-down current does not need to be as big as the true pull-down current, as long as the M:1 ratio is taken into consideration in the subsequent calculation of the RC time constant. Using a smaller representative copy of the pull-down current thus reduces power consumption. In the above description of current mirror 440b, transistor 616, or some other circuits that can replicate the pull-down current, may be referred to as the pull-down replica circuit.

FIG. 6B is a schematic of an example word line regulator 420 and another example current mirror 440c for obtaining a representative copy of the pull-up current, in accordance with examples as disclosed herein. Regulator 420 is the same as described above, and is thus not repeatedly described. The current mirror 440c is configured to obtain a representative copy of the pull-up current (Iₚᵤ). The current mirror 440c is configured differently from current mirror 440a. As shown in FIG. 6B, current mirror 440c includes a replica circuit and an op-amp 622. The replica circuit, in one example, includes a transistor 624 and a transistor 626 (both can be, but are not necessarily, NMOS transistors). Transistors 624 and 626 are coupled in series, such that the source terminal of the transistor 624 is coupled with the drain terminal of the transistor 626. The drain terminal of transistor 624 is coupled to the power supply; and the source terminal of transistor 626 is coupled to the electrical ground (denoted by V_{N}). It is understood that while the replica circuit in current mirror 440c only shows two transistors configured in the manner as shown in FIG. 6B, any number of transistors in any other configurations may be used for making a replica circuit. The transistors 624 and 538 have a ratio of 1:M in terms of their areas (e.g., the widths of the transistor 624 and the transistor 538 has a ratio of 1:M, if they have the same length), similar to those described above in current mirror 440a.

Op-amp 622 is coupled between regulator 420 and the replica circuit comprising transistors 624 and 626. Specifically, one input terminal of op-amp 622 (e.g., the negative terminal) is coupled to the output terminal 543 of regulator 420; the other input terminal of op-amp 622 (e.g., the positive terminal) is coupled to the node 545, which is also the source terminal of transistor 624 or the drain terminal of transistor 626. Op-amp 622's output terminal is coupled with the gate terminal of transistor 626. The voltage at the node 545 (also referred to as the source voltage, which is voltage at the source terminal of transistor 624) is forced to be equal to the word line voltage V_{wlrv} at the output terminal of regulator 420, because the op-amp 622 has a high gain. In this manner, the pull-up current can be replicated from regulator 420.

FIG. 6C is a schematic of an example word line regulator 420 and an example current mirror 440d for obtaining a representative copy of the resistor divider current, in accordance with examples as disclosed herein. In some examples, current mirror 440d is coupled with op-amp 548. As described above, in some examples, transistor 552 is turned off (e.g., by applying a low voltage or ground voltage to the gate terminal of transistor 552) and therefore the resistor divider comprising resistors 544 and 546 is disconnected from ground 554. Thus, the resistor divider current (denoted by Iᵣₑₛ or I_{_RES}) flows through op-amp 548, rather than to the electrical ground 554. The resistor divider current flowing through op-amp 548 may pass through, for example, certain transistors or branches (similar to those described above). The resistor divider current can therefore be replicated or “mirrored” out by current mirror 440d. For instance, current mirror 440d may use any of the above-described configurations to form a replica circuit. For example, current mirror 440d can have a simple NMOS transistor with the gate terminal coupled a corresponding transistor or branch in op-amp 548. Current mirror 440d can therefore obtain the representative copy of the resistor divider current Iᵣₑₛ. The representative copy of the resistor divider current is denoted as I_{res_replica}.

FIG. 6D is a schematic of an example word line regulator 420 and an example current or voltage source 662 for obtaining a representative copy of the resistor divider current, in accordance with examples as disclosed herein. FIG. 6D shows another way to obtain a representative copy of the resistor divider current in a test setting. In FIG. 6D, the regulator 420 is not in operation (e.g., a read or program operation). Instead, the resistor divider (comprising resistors 544 and 546) is disconnected from the regulator 420 at node 543 (which is the output terminal of regulator 420) and at node 549 (which is the output terminal of op-amp 548). The disconnection of the resistor divider from other parts of regulator 420 can be implemented using switches placed at nodes 543 and 549 (not shown). These switches can be FET switches that are controllable to: (1) disconnect the resistor divider from other parts of regulator 420 when measuring currents flowing through the resistor divider or measuring voltages at the output terminal of the regulator, respectively; and (2) to reconnect the resistor divider to other parts of regulator 420 when the measurements are completed.

During testing, transistor 552 is turned on (e.g., by applying a sufficiently large positive voltage on its gate terminal). A current or voltage source 662 (in FIG. 6D, 662 is shown to be a current source denoted by I_{_DC}) is controllable (e.g., by a testing equipment or a test person) to provide a plurality of pre-determined currents or voltages to the resistor divider. For example, if a known voltage is applied, the current flowing through the resistor divider comprising resistors 544 and 546 can be measured. This is because the resistor divider current Iᵣₑₛ is a function of the voltage at the node 543 (denoted by V_{wrlv}). If a current is applied to the resistor divider, then the voltage at the node 543 (denoted by V_{wrlv}) can be measured. During the testing process, multiple known voltages or known currents can be applied to the resistor divider. A look-up table or a relation between the V_{wrlv} and the Iᵣₑₛ can be established. Therefore, if the V_{wrlv} is measured in real time, the Iᵣₑₛ can be easily obtained by using the look-up table or a relation. The look-up table or the relation can be stored in, for example, RC constant manager 410 shown above in FIG. 4. They can be accessed by a controller using firmware commands.

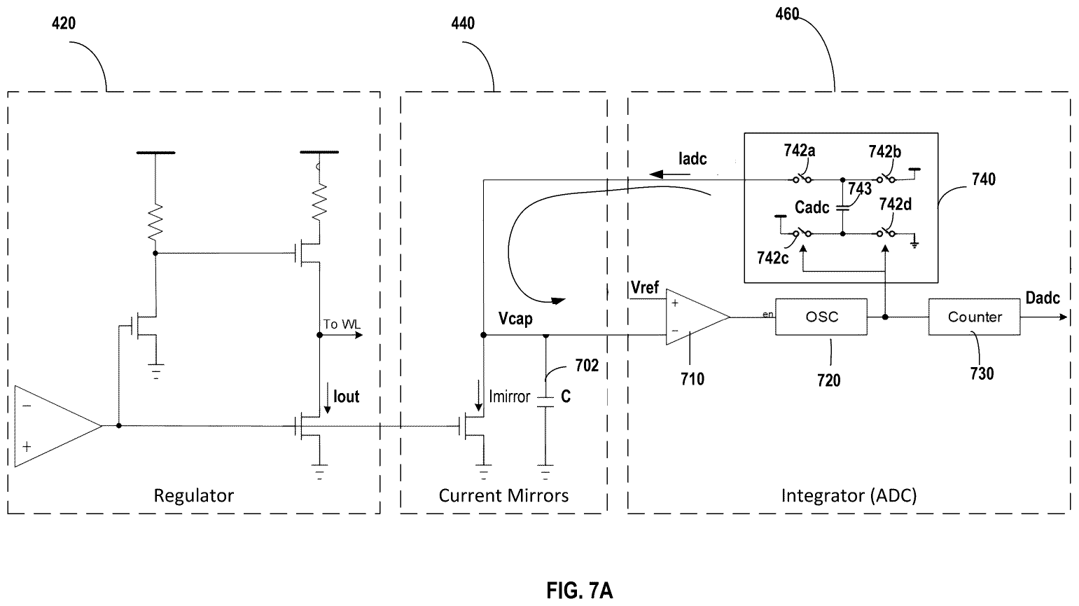

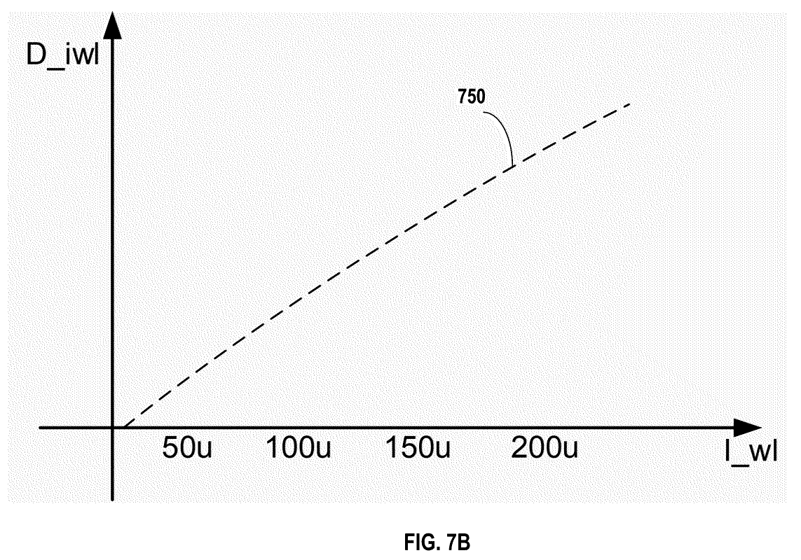

The above descriptions provide examples of regulator 420 and current mirrors 440. FIG. 7A is a schematic of an example RC-sensor circuit including a regulator 420, current mirrors 440, and an integrator 460, in accordance with examples as disclosed herein. Current mirrors 440 may be any one or more of the current mirrors 440a-440d described above. In some cases, the resistor divider current can be measured during testing or manufacturing, and a look-up table or curve can be established for faster calculations. In FIG. 7A, regulator 420 and current mirrors 440 are simplified for illustration purpose. In one example, integrator 460 includes an analog-to-digital converter (ADC). The ADC is coupled to one or more current mirrors 440. As described above, current mirrors 440 obtain the representative copies of the pull-up current, pull-down current, and the resistor divider current. Based on these representative copies, the word line current I_{wl} can be obtained based on equation [1] described below. Therefore, in FIG. 7A, the current flowing out of current mirrors 440 can be the word line current. This current is equal to the ADC current (denoted by I_{adc}) from integrator 460 when the loop between current mirrors 440 and integrator 460 is stabilized.

As shown in FIG. 7A, integrator 460 (e.g., an ADC) includes a comparator 710 coupled to the one or more current mirrors 440. Comparator 710 is configured to receive an output voltage of the one or more current mirrors 440 and a reference voltage (denoted by V_{ref}). Comparator 710 compares the output voltage of the current mirrors 440 and the reference voltage V_{ref}, and provides an output signal to an oscillator 720. Oscillator 720 can be controlled by the output signal of comparator 710 to generate pulses at certain frequencies to drive the charge pump 740. Depending on the voltage level of output signal of comparator 710, the pulse repetition rate (or pulse frequency, pulse time interval) of the output signal from oscillator 720 can be changed.

Charge pump 740 may include a switch capacitor structure, which uses switches 742a-742d to connect and disconnect capacitors (e.g., capacitor 743, denoted by C_{adc}) in a specific manner, effectively transferring charge to, from, or between capacitors to form an output voltage or current. FIG. 7A shows 4 switches and one capacitor for illustration, but it is understood other charge pump structures may also be used, including more or fewer switches or capacitors, or a different configuration thereof. In this case, switches 742a-742d of charge pump 740 are controlled by the pulses generated by oscillator 720 to form the ADC current denoted by I_{adc}. When the ADC current is controlled to be the same as the output current of the current mirrors (which is a representative copy of the word line current I_{wl}), the feedback loop between current mirrors 440 and integrator 460 is stabilized. The oscillator 720 also provides its output pulses to counter 730. Thus, when the loop is stable, the digital outputs (e.g., digital counts) of the counter 730 are digital data representing the integration of the word line current I_{wl}. The below equation [4] provides the mathematical relation between the integration of the representative copy of the word line current (denoted by Iₘᵢᵣᵣₒᵣ), the count provided by the counter 730 (denoted by D_{adc}), the capacitance of the capacitor 743 in charge pump 740 (denoted by C_{adc}), the power supply voltage (denoted by Vₑₑ), and the reference voltage to the comparator 710 (denoted by V_{ref}).

$$\int {I}_{mirror} dt = {D}_{adc} * {C}_{adc} * ( 2 {V}_{cc} - {V}_{ref} ) \qquad [ 4 ]$$

The integration performed by integrator 460 can be applied to multiple time intervals. As shown above in FIG. 5B, for example, the integration can be performed for a time interval between time 0 and T₁ and another time interval between time 0 and T₂. The results of the multiple integrations are multiple ADC counts. For example, a first ADC count may represent the integration of the word line current over the first time interval (from time 0 to T₁), and the second ADC count may represent the integration of the word line current over the second time interval (from time 0 to T₂). The integration of current results in charge. Thus, the first and second ADC counts represent a first charge and a second charge, respectively. The RC time constant can be calculated based on the ratio of the first count (denoted by D_{adc1}) and the second count (denoted by D_{adc2}), as shown in equation [5] below.

$$\frac{{\int }_{T 0}^{T 1} {I}_{mirror} dt}{{\int }_{T 0}^{T 2} {I}_{mirror} dt} = \frac{{D}_{adc 2}}{{D}_{adc 1}} \qquad [ 5 ]$$

The integrator 460 described above can operate at a high speed and the loop can be stabled over a short period of time. For example, by properly configuring a capacitor 702, a dominant pole can be generated for stabilizing the ADC. Other techniques may also be used to create a stable loop for the ADC. The settling time of this ADC shown in FIG. 7A can be configured to be short, enabling real-time measurement of the RC time constant, as described in more detail below.

As described above, the representative copy of the word line current is obtained based on obtaining the representative copies of the pull-up current, pull-down current, and the resistor divider current in the regulator. The output of current mirrors 440 in FIG. 7A is a representative copy of the word line current from the methods describe from FIG. 6A, FIG. 6B and FIG. 6C. Current mirrors 440 may only provide a representative copy of net current of the pull-up current and the pull-down current. Current mirror 440 may have an offset (for example, due to transistor mismatch) to the net current of word line. Thus, the output of the integrator 460 needs to be adjusted with the resistor divider current, which is available through the look-up table or curve.

While the RC sensor circuit shown in FIG. 7A can operate in real time to provide the RC time constant of a word line, in some examples, current mirror trim-by-die (TBD) techniques can be used to improve the accuracy of the current mirrors. With reference back to FIG. 6D, for example, when applying the TBD techniques, the regulator 420 can be disconnected from the word line (e.g., using the techniques similar to those shown in FIG. 6D and described above). An external current source (e.g., current source 662) can be used to apply a known DC current into the node 543, which is the input node to the current mirrors 440 and integrator 460. The current mirrors 440 generates representative copies of the known DC current, and the integrator 460 outputs the digital counts representing the integration of the known DC current. Different values of the DC current can be used and the digital outputs from the integrator 460 can be obtained for the various DC current values.

FIG. 7B is an example relation between a word line current (using the known DC current values, denoted b I_{wl}) and the digital data representing the word line current (using the count of the integrator 460 output, denoted by D_{iwl}), in accordance with examples as disclosed herein. Curve 750 can be obtained by forcing multiple known DC currents as described above and obtaining the digital counts at the output of the integrator 460. This relation can be stored as a look-up table or curve in, for example, RC constant manager 410 shown in FIG. 4. In real-time operation, when a digital count is obtained at the integrator 460 output, the word line current can be obtained quickly using the stored look-up table or curve.

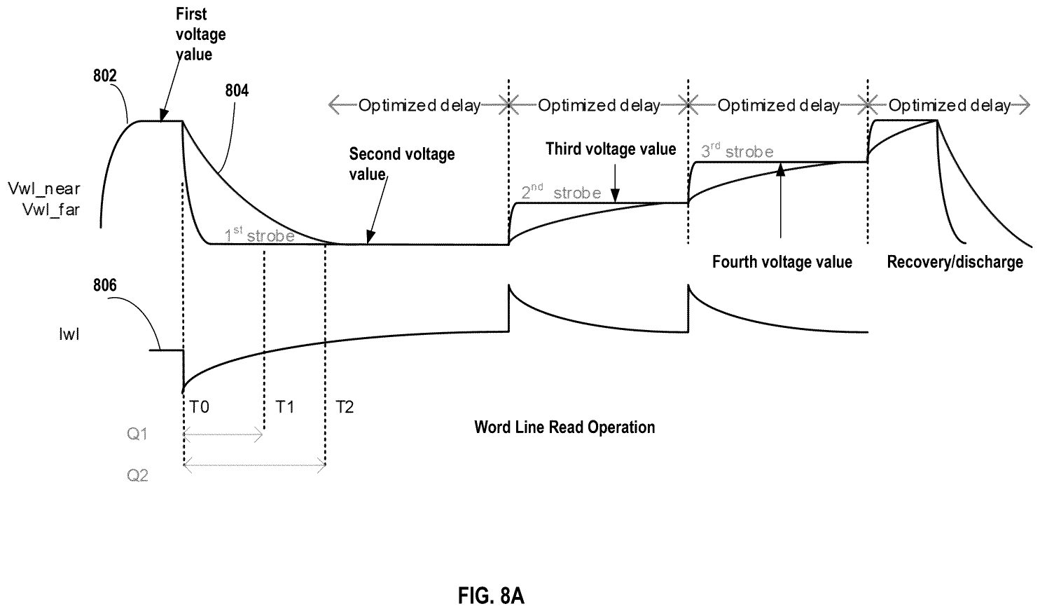

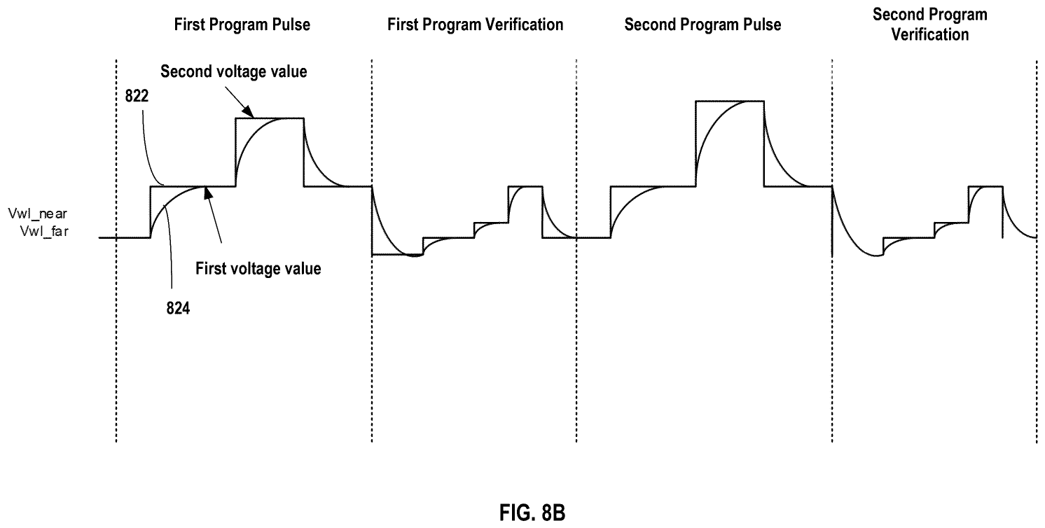

The RC sensor circuit described above can be used in real time to obtain the RC time constant. The RC time constant in turn can be used to obtain a time delay of the word line for propagating the word line voltage from the near end to the far end. Thus, this time delay can be used in subsequent steps or time periods in a same operation. FIG. 8A are example relations of a near-end word line voltage, a far-end word line voltage, and a word line current with respect to time in a read operation, in accordance with examples as disclosed herein. Curves 802, 804, and 806 represent the near-end word line voltage waveform, the far-end word line voltage waveform, and the word line current waveform, respectively, during an example read operation. During a read operation of a multiple level memory cell (e.g., an MLC, TLC, QLC, etc.), a regulator applies a voltage at the near-end of a selected word line (i.e., the end of the word line proximate to the regulator that drives the word line). This word line voltage is also referred to as the output voltage of the regulator, the near-end word line voltage, or a reference voltage. The below description uses the near-end word line voltage. The near-end word line voltage propagates to the far end and becomes the far-end word line voltage, which is compared to the one or more of the multiple threshold voltage (Vt) levels of the multiple level memory cell. Using an MLC memory cell as an example, it has three threshold voltage levels (Vₜ₁, Vₜ₂, and Vₜ₃). Thus, during a read operation, the near-end word line voltage is increased or decreased, and thus, the far-end word line voltage is also increased or decreased to compared to the different threshold voltage levels (Vₜ₁, Vₜ₂, and Vₜ₃) for reading the data stored in the memory cell. During the read operation of a memory cell associated with a selected word line, other word lines are applied with a passing voltage (Vₚₐₛₛ), which is typically higher than all the threshold voltages.

With reference to FIG. 8A, during this example read operation, a regulator (e.g., regulator 420) may initially apply a low voltage to the near-end of a selected word line. As a result, as shown by curve 802, the near-end word line voltage (V_{wl_near}) ramps down from a first voltage value (e.g., the highest level) at time T₀ to a second voltage value (e.g., the lowest level) after a short time delay. Curve 804 shows that the far-end word line voltage (V_{wl_far}) ramps down from the first voltage level at time T₀ to the second voltage level at time T₂. Due to the word line RC, the time delay for ramping down the far-end word line voltage (V_{wl_far}) is longer than the time delay for ramping down the near-end word line voltage. That is, there is a propagation delay between the near-end word line voltage and the far-end word line voltage. Curve 806 shows the corresponding ramping up of the word line current (I_{wl}) from an initial value at time T₀ to a final value (e.g., zero current).

As described above, during a read operation, the regulator drives the selected word line to different voltage levels in an incremental manner. Conventionally, the regulator cannot increase the word line voltage to the next value, until a sufficiently long time period has passed so that the far-end word line voltage (V_{wl_far}) has settled to its final value. The time period that the regulator needs to keep the near-end word line voltage unchanged depends on the worst-case word line RC time constant. But as described above, this results in a slower read operation because not all word lines have the worst-case RC time constant.

FIG. 8A shows that during a first ramping time period or a first strobe in a read operation, the selected word line's RC time constant can be measured using the techniques described above. Specifically, a strobe corresponds to a time period during which the regulator keeps the near-end word line voltage (or its output voltage) unchanged. As shown by curve 802 in FIG. 8A, the first strobe corresponds to the time period between the time T₀ (which is when the near-end word line voltage starts to change from the first voltage value to the second voltage value) and the time the near-end word line voltage starts to change from the second voltage value to the third voltage value. As shown by curve 804 of FIG. 8A, the first ramping time period is the time period between time TO and the time the far-end word line voltage settles to the second voltage value, i.e., it is the time period for the far-end word line voltage to ramp down to its final value. FIG. 8A shows that the time period corresponding to the first strobe is longer than the first ramping time period, which is only the time that is required for the far-end word line voltage to settle. The time period corresponding to the first strobe may correspond to the time required for settling a far-end word line voltage of a word line having the worst-case RC time constant (e.g., the largest RC time constant among all word lines). So if the selected word line is not a worst-case word line, the first ramping time period may be smaller in timing than the time period corresponding to the first strobe. If the selected word line is the worst-case word line, the first ramping time period is the same as the time period of the first strobe (i.e., the worst-case ramping time period).

Using the RC sensor circuit (e.g., circuit 402) descried above, an integration of a representative copy of the word line current I_{wl} can be performed for multiple time intervals (e.g., time intervals between T₀ and T₁, and between T₀ and T₂) during the first ramping time period. And the RC time constant can be calculated based on the ratio of the charges obtained from the integration. This process for obtaining the RC time constant can be performed within the first ramping time period of the first strobe. Therefore, the subsequent ramping time period allocated to the selected word line can be obtained.

Referring to FIG. 8A, for the second ramping time period (in the second strobe), the regulator changes the near-end word line voltage (V_{wl_near}) from the second voltage value (e.g., the lowest voltage level) to a third voltage value that is higher than the second voltage value (but not the highest level). Based on the RC time constant obtained during the first ramping time period, the time delay for the far-end word line voltage (V_{wl_far}) to settle can be calculated based on the second and third voltage values. Therefore, the regulator does not need to wait for a long time period corresponding to the worst-case word line RC time constant before it further changes the near-end word line voltage to the next value. Instead, with the knowledge of the exact time delay needed in the second strobe, the regulator can be controlled (e.g., by a local controller 135 or a memory system controller 415) to increase the near-end word line voltage to the next value when the second ramping time period completes, or shortly thereafter. In this case, the time period of the second strobe can be reduced to be substantially same as the second ramping time period, and no or minimum time is wasted in the read operation. The same process can be repeated for the subsequent strobes. For example, the RC time constant obtained during the first ramping time period or the second ramping time period can be used to calculate the third ramping time period. After the regulator increases the near-end word line voltage from the third voltage value to a fourth voltage value, it keeps the near-end word line voltage at the fourth voltage value for approximately the third ramping time period just sufficient for the far-end word line voltage to settle. And then the regulator can further increase or decrease the near-end word line voltage for the subsequent steps of the read operation. The time period of the third strobe thus can also be reduced to be substantially the same as the third ramping time period for ramping up and settling the far-end word line voltage. Overall, the read operation can be performed within a short period of time.

In FIG. 8A, two time intervals are shown for calculating the RC time constant of the selected word line. The two time intervals are between time point T₀ and time point T₁, and between time point T₀ and time point T₂. The selection of the time points T₁ and T₂ need be controlled such that no time points after the settling of the far-end word line voltage (e.g., after far-end word line voltage arrives at the final value or within a threshold of the final value) should be selected. Furthermore, the time points T₁ and T₂ may not be very close to each other for improving calculation accuracy. While FIG. 8A only shows two time points T₁ and T₂, more time points can be used (e.g., T₃, T₄, etc.) for integrating the word line current to obtain the RC time constant. The controlling of the selection of time points for integration can be performed by a controller such as the local controller 135 or the memory system controller 115.

As described above, the measuring of the RC time constant can also be used to evaluate if a word line is defective. Therefore, if after an abnormally long period of time, the far-end word line voltage (curve 804) still does not settle and/or the word line current I_{wl} (curve 806) does not approach its final value (e.g., zero), it may mean that there is a leakage current or likely a short between the word line and other part of the memory device. On the other hand, if the far-end word line voltage settles to its final value in an abnormally short period of time, it may mean that the word line is broken, and thus the device may an open word line defect.

In addition, the real-time measurement of the RC time constant of a word line can be used to determine an overdrive of the word line. An overdrive of the word line means that the regulator initially drives the word line to a voltage that is higher than the target voltage value and then reduces the voltage down to the target voltage value. For example, in the time period of the second strobe in FIG. 8A, the regulator can initially apply a voltage that is slightly higher than the third voltage value and then reduce the voltage down to the third voltage value (which is the final voltage value for the second strobe). This way, the settling of the far-end word line voltage can be faster. The real-time measurement of the RC time constant can also be used to evaluate the amount of overdrive needed. For example, if a word line has a relatively small RC time constant, then a smaller overdrive may be applied; and if a word line has a relatively high RC time constant, then a larger overdrive may be needed.

Furthermore, FIG. 8A illustrates that the regulator drives the near-end word line voltage (curve 802) from low to high in a read operation. The opposite can also be performed. That is, the regulator can drive the near-end word line voltage or another circuit line voltage from high to low. The same or substantially similar method of measuring RC time constant can be performed, and the overall time period of the read operation can be reduced.

FIG. 8B are example relations of near-end word line voltage and far-end word line voltage with respect to time in a program operation, in accordance with examples as disclosed herein. Curve 822 represents the word line voltage at near-end (V_{wl_near}) and curve 824 represents the word line voltage at far-end (V_{wl_far}). Programming a multiple level memory cell (e.g., MLC, TLC, QLC, etc.) involves storing data by adjusting the charge levels within the memory cells to represent multiple bits per cell. Programming is usually controlled by a controller such as local controller 135 and/or system controller 115. Programming memory cells typically involves two phases, i.e., a data programming phase and a verification phase. The two phases are repeated to program data into the memory cells. During the programming phase, a regulator drives a program pulse having incremental voltage values because there are multiple levels of threshold voltages (e.g., Vₜ₁, Vₜ₂, and Vₜ₃) for a multiple-level memory cell. During a verification phase, the controller verifies the programmed data and if the data is verified, the particular memory cell is programmed. If the data is not verified, additional program pulses are used, and these additional program pulses may have higher or lower voltage levels.

FIG. 8B is a simplified diagram illustrating a program operation of memory cells. As shown in FIG. 8B, the RC time constant of a selected word line for program operation can also be obtained in a way that is similar to those described above. For example, in the first program pulse phase shown in FIG. 8B, the regulator can drive the near-end of a selected word line to different voltage values. Therefore, the RC time constant can be measured during the time period when the regulator keeps the word line voltage at the first voltage value. Then the regulator changes the near-end word line voltage to a second voltage value. The RC time constant can be used to calculate the ramping up or ramping down time for the far-end word line voltage to settle to the second voltage value. As a result, the regulator only needs to keep the word line voltage at the second voltage value for a time period that allows the far-end word line voltage to settle, and no longer (or slightly longer). The regulator can perform similarly for the subsequent steps in the first program pulse phase.

In some examples, the RC time constant of a word line is measured during a program verification phase, rather than in a program pulse phase. This is because the read operation and the program verification operation use the same regulator; while the program (or write) operation may use a different regulator. Regardless of the regulator used, the real-time RC time constant of a word line can be measured using the techniques as described above and used for optimizing the subsequent steps in the program verification phase. This way, the overall program time can be reduced for the program operation.

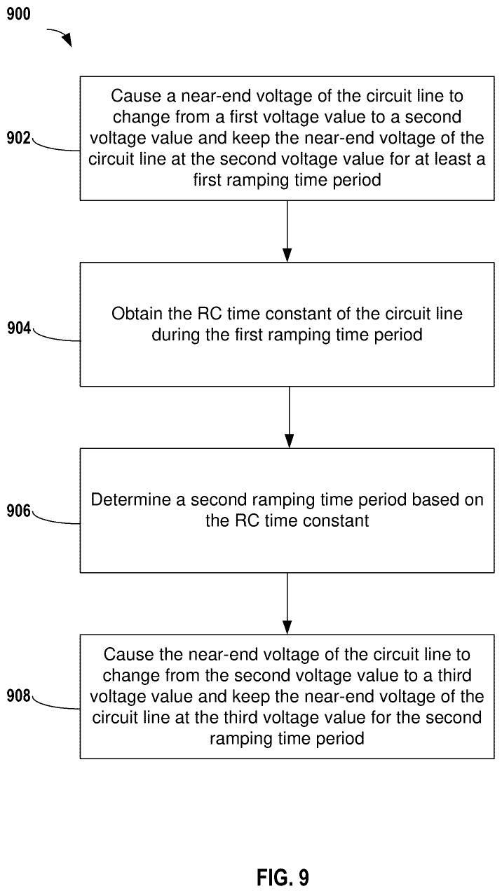

FIG. 9 illustrates a flowchart showing a method or methods 900 that support techniques for using real-time RC time constant measurement to optimize an access operation in accordance with examples as disclosed herein. As shown in FIG. 9, a memory controller (e.g., a memory system controller 115 and/or a local controller 135) may store instructions and issue firmware commands to perform the one or more steps in method 900. Referring to both FIGS. 8A and 9, in step 902, the memory controller may cause a near-end voltage of the circuit line to change from a first voltage value to a second voltage value and keep the near-end voltage of the circuit line at the second voltage value for at least a first ramping time period (e.g., shown by curves 802 and 804 of FIG. 8A). In step 904, the memory controller obtains the RC time constant of the circuit line during the first ramping time period. For example, using two time intervals from T₀ to T₁ and from T₀ to T₂, the RC time constant can be obtained based on the integration of the word line current as described above. In step 906, the memory controller determines a second ramping time period based on the RC time constant (e.g., the ramping time period in second strobe shown by curve 804 in FIG. 8A). In step 908, the memory controller causes the near-end voltage of the circuit line to change from the second voltage value to a third voltage value and keep the near-end voltage of the circuit line at the third voltage value for the second ramping time period (e.g., shown by curves 802 and 804 of FIG. 8A). The above steps can be applied in a read operation shown in FIG. 8A or a program operation shown in FIG. 8B and described above. In addition, whether in a read operation or a program operation, the second voltage value may be greater than the first voltage value, and wherein the third voltage value may be greater than the second voltage value; or vice versa. For a program operation, and the first time period can be within a program pulse phase or a validation phase of the program operation.

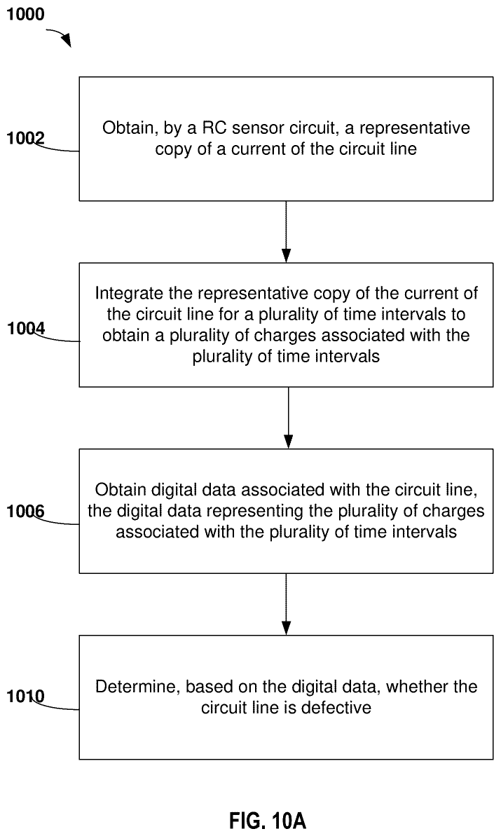

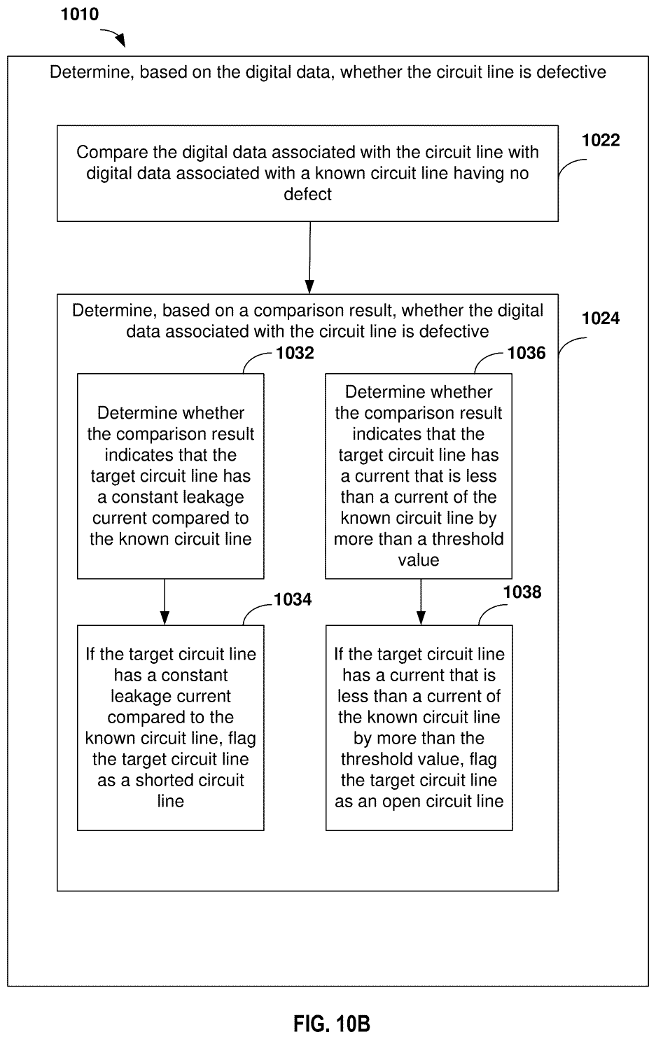

FIG. 10A illustrates a flowchart showing a method or methods 1000 that support techniques for detecting defects in a target circuit line, in accordance with examples as disclosed herein. Method 1000 can be performed at least partially using a memory device comprising a memory array, a resistor-capacitor (RC) sensor circuit, and a memory controller. In method 1000, step 1002 obtains, by the RC sensor circuit (e.g., circuit 402), a representative copy of a current of the circuit line. Step 1004 integrates (e.g., by an integrator 460) the representative copy of the current of the circuit line for a plurality of time intervals to obtain a plurality of charges associated with the plurality of time intervals. Step 1006 obtains (e.g., by the ADC of integrator 460) digital data associated with the circuit line. The digital data represents the plurality of charges associated with the plurality of time intervals. Step 1010 determines, based on the digital data, whether the circuit line is defective.

FIG. 10B illustrates a flowchart showing details of a method or methods 1010 for determining, based on the digital data, whether the circuit line is defective. Step 1022 compares the digital data associated with the circuit line with digital data associated with a known circuit line having no defect. Step 1024 determines based on a comparison result, whether the digital data associated with the circuit line is defective. For instance, in step 1032, it is determined (e.g., by a memory device, memory system, or a host system) whether the comparison result indicates that the target circuit line has a constant leakage current compared to the known circuit line. If so, step 1034 flags the target circuit line as a shorted circuit line. In another example, in step 1036, it is determined whether the comparison result indicates that the target circuit line has a current that is less than a current of the known circuit line by more than a threshold value. If so, step 1038 flags the target circuit line as an open circuit line.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A resistor-capacitor (RC) sensor circuit, comprising:
a regulator configured to drive a circuit line;
one or more current mirrors coupled to the regulator to obtain a representative copy of a current of the circuit line; and
an integrator comprising an analog-to-digital converter (ADC), the ADC being coupled to the one or more current mirrors to receive the representative copy of the current of the circuit line and being configured to:
integrate the representative copy of the current of the circuit line for a plurality of time intervals to obtain a plurality of charges associated with respective time intervals,
wherein the plurality of time intervals are within a first ramping time period for ramping a far-end voltage of the circuit line from a first voltage value to a second voltage value, and
output digital data that is used to calculate an RC time constant of the circuit line, wherein the digital data is a representation of the plurality of charges.

2. The RC sensor circuit of claim 1, wherein the regulator comprises:
one or more operational amplifiers configured to receive one or more reference voltages; and
a resistor divider coupled to the one or more operational amplifiers, the resistor divider being provided with a resistor divider current; and
a plurality of transistors coupled to at least one of the one or more operational amplifiers, the plurality of transistors being configured to generate a pull-up current and a pull-down current, wherein the current of the circuit line is obtained based on the pull-up current, the pull-down current, and the resistor divider current.

3. The RC sensor circuit of claim 1, wherein the one or more current mirrors comprises:
a first current mirror configured to obtain a representative copy of a pull-up current generated in the regulator; and
a second current mirror configured to obtain a representative copy of a pull-down current generated in the regulator.

4. The RC sensor circuit of claim 3, wherein the first and second current mirrors are sized such that the representative copies of the pull-up current and the pull-down current have a 1/M ratio with respect to the pull-up current and pull-down current generated in the regulator, respectively, wherein M is a positive number.

5. The RC sensor circuit of claim 3, wherein the first current mirror and the second current mirror comprise a pull-up replica circuit and a pull-down replica circuit configured to obtain the representative copies of the pull-up current and the pull-down current respectively.

6. The RC sensor circuit of claim 3, wherein the first current mirror comprises:
a replica circuit; and
an operational amplifier coupled between the regulator and the replica circuit.

7. The RC sensor circuit of claim 3, further comprising:
a third current mirror coupled to the regulator, the third current mirror being configured to obtain a representative copy of a resistor divider current generated in the regulator.

8. The RC sensor circuit of claim 3, further comprising:
a voltage source or a current source controllable to provide a plurality of pre-determined voltages or currents, respectively, to a resistor divider of the regulator; and
one or more switches controllable to disconnect the resistor divider from other parts of the regulator when measuring currents flowing through the resistor divider or measuring voltages at the output of the regulator, respectively.

9. The RC sensor circuit of claim 1, wherein the ADC comprises:
a comparator coupled to the one or more current mirrors, the comparator being configured to receive an output voltage of the one or more current mirrors and a reference voltage;
an oscillator coupled to an output of the comparator;
a charge pump coupled to the oscillator and the one or more current mirrors, wherein the charge pump, the comparator, and the oscillator forms a feedback loop to output digital output voltage pulses representing the integration of the representative copy of the current of the circuit line; and
a counter configured to generate the digital data based on the digital output voltage pulses.

10. The RC sensor circuit of claim 1, wherein the digital data comprise a first ADC count and a second ADC count representing a first charge and a second charge of the plurality of charges, respectively, and the RC time constant is a ratio of the first ADC count and the second ADC count.

11. The RC sensor circuit of claim 1, wherein the circuit line is a word line in a memory device.

12. A memory device comprising:
a memory array;
a memory controller; and
a resistor-capacitor (RC) sensor circuit comprising
a regulator configured to drive a circuit line,
one or more current mirrors coupled to the regulator to obtain a representative copy of a current of the circuit line, and
an integrator comprising an analog-to-digital converter (ADC), the ADC being coupled to the one or more current mirrors to receive the representative copy of the current of the circuit line and being configured to:
integrate the representative copy of the current of the circuit line for a plurality of time intervals to obtain a plurality of charges associated with respective time intervals,
wherein the plurality of time intervals are within a first ramping time period for ramping a far-end voltage of the circuit line from a first voltage value to a second voltage value, and
output digital data that is used to calculate an RC time constant of the circuit line, wherein the digital data is a representation of the plurality of charges.

13. A memory device comprising:
a memory array;
a regulator;
a resistor-capacitor (RC) sensor circuit configured to sense a RC time constant of a circuit line in the memory device; and
a memory controller configured to:
cause a near-end voltage of the circuit line to change from a first voltage value to a second voltage value and keep the near-end voltage of the circuit line at the second voltage value for at least a first ramping time period;
obtain the RC time constant of the circuit line during the first ramping time period;
determine a second ramping time period based on the RC time constant; and
cause the near-end voltage of the circuit line to change from the second voltage value to a third voltage value and keep the near-end voltage of the circuit line at the third voltage value for the second ramping time period, wherein the second ramping time period is smaller than the first ramping time period.

14. The memory device of claim 13, wherein the memory controller is configured to perform a read operation, and wherein the second voltage value is greater than the first voltage value, and wherein the third voltage value is greater than the second voltage value.

15. The memory device of claim 13, wherein the memory controller is configured to perform a program operation, and wherein the first ramping time period is within a validation phase of the program operation.

16. The memory device of any of claim 13, wherein the memory controller is configured to perform a program operation, and the first ramping time period is within a program pulse phase of the program operation.

17. A method for detecting defects in a target circuit line, the method being performed at least partially using a memory device comprising a memory array, a resistor-capacitor (RC) sensor circuit, and a memory controller, the method comprising:
obtaining, by the RC sensor circuit, a representative copy of a current of the circuit line;
integrating the representative copy of the current of the circuit line for a plurality of time intervals to obtain a plurality of charges associated with the plurality of time intervals;
obtaining digital data associated with the circuit line, the digital data is a representation of the plurality of charges associated with the plurality of time intervals; and
determining, based on the digital data, whether the circuit line is defective.

18. The method of claim 17, wherein determining whether the circuit line is defective comprises:
comparing the digital data associated with the circuit line with digital data associated with a known circuit line having no defect; and
determining, based on a comparison result, whether the digital data associated with the circuit line is defective.

19. The method of claim 18, wherein determining, based on the comparison result, whether the digital data associated with the circuit line is defective comprises:
determining whether the comparison result indicates that the target circuit line has a constant leakage current compared to the known circuit line; and
if the target circuit line has a constant leakage current compared to the known circuit line, flagging the target circuit line as a shorted circuit line.

20. The method of claim 18, further comprising:
determining whether the comparison result indicates that the target circuit line has a current that is less than a current of the known circuit line by more than a threshold value; and
if the target circuit line has a current that is less than a current of the known circuit line by more than the threshold value, flagging the target circuit line as an open circuit line.
